(19) United States
(12) Patent Application Publication
(10) Pub. No.: US 2015/0225845 A1
(43) Pub. Date: Aug. 13, 2015

(54) METHOD FOR FORMING METAL OXIDE THIN FILM AND DEVICE FOR PRINTING METAL OXIDE THIN FILM

(71) Applicant: Electronics and Telecommunications Research Institute, Daejeon (KR)

(72) Inventors: Jonghyurk PARK, Daejeon (KR); Jong-Heon YANG, Daejeon (KR); Seunghyup YOO, Daejeon (KR); Jungmin CHOI, Daejeon (KR); Hye Yong CHU, Daejeon (KR); Chi-Sun HWANG, Daejeon (KR)

(73) Assignee: Electronics and Telecommunications Research Institute, Daejeon (KR)

(21) Appl. No.: 14/608,856

(22) Filed: Jan. 29, 2015

(30) Foreign Application Priority Data
Feb. 12, 2014 (KR) 10-2014-0016086
Jun. 25, 2014 (KR) 10-2014-0078173

(51) Int. Cl. C23C 16/40; C23C 16/48; C23C 16/511; C23C 16/448

(52) U.S. Cl. CPC C23C 16/40; C23C 16/448; C23C 16/484; C23C 16/511; C23C 16/48

(57) ABSTRACT

Provided is a metal oxide thin film forming method including: vaporizing a first metal oxide precursor; allowing the vaporized first metal oxide precursor to flow into a mixture chamber by using a first carrier gas; injecting the flowed first metal oxide precursor on a substrate through a micro nozzle connected to the mixture chamber to form a first metal oxide precursor layer on the substrate; and emitting electromagnetic waves to the first metal oxide precursor layer to form a first metal oxide layer.

### CROSS-REFERENCE TO RELATED APPLICATIONS

This U.S. non-provisional patent application claims priority under 35 U.S.C. §119 of Korean Patent Application Nos. 10-2014-0016086, filed on Feb. 12, 2014, and 10-2014-0078173, filed on Jun. 25, 2014, the entire contents of which are hereby incorporated by reference.

### BACKGROUND OF THE INVENTION

The present invention disclosed herein relates to a metal oxide thin film forming method and a metal oxide thin film printing device, and more particularly, to a metal oxide thin film forming method and a metal oxide thin film printing device using vapor jet printing.

A metal oxide thin film may be used for a gate insulation layer of a metal-oxide-semiconductor field-effect transistor (MOSFET) as a typical nonconductor or may be used for a display and a transparent electrode of an energy device as a typical conductor. Recently, the metal oxide thin film is developed as a semiconductor to replace silicon. For example, the metal oxide thin film is used for a charge transport layer of a backplane thin film transistor (TFT) or a transparent electronic device TFT of an organic light-emitting diode (OLED) or an ultra definition (UD) display. Especially, a zinc oxide (ZnO) thin film among metal oxide materials is a material of which conductivity and semi-conductivity are controllable according to an oxygen content or a doping material. A thin film transistor applying the ZnO thin film as a charge transport layer may be applied to a large-sized display including a liquid crystal display (LCD) and an OLED display.

In general, a metal oxide thin film in use is mainly manufactured through a vapor deposition process such as sputtering and e-beam. There processes may provide a high quality oxide layer but may have limitation in an available bottom material or substrate because particles having high-temperature condition or high kinetic energy are used. Moreover, in order to form a fine pattern of the metal oxide thin film, an expensive optical etching process is required.

Moreover, in the case of a chemical vapor deposition (CVD) process or a plasma-enhanced chemical vapor deposition (PECVD) process, they may be performed at a relatively low vacuum and a precursor may be deposited on an entire substrate by using a shower head to form a metal oxide thin film. That is, the CVD or PECVD process also requires an additional patterning process. Moreover, since the CVD or PECVD process may damage a substrate due to high energy reaction, it is difficult to apply the CVD or PECVD process to a flexible substrate.

Moreover, among printing techniques for direct fine patterning, wet-based screen printing, inkjet printing, and offset printing are used typically. In the case of an organic based material, such printings are developed for mass production. In the case of a wet process, since substrate intrusion caused by a solvent is great and an interference between interlayer materials in a layered structure exists, a device using a multilayer structure is limited in utilization. An organic vapor-jet printing (OVJP) process improving such an issue is a process for heating and vaporizing an organic semiconductor, moving the vaporized organic semiconductor to a nozzle by using an inert carrier gas, and jet-injecting the vaporized organic semiconductor. In the case of a vapor-jet method, since a solvent is not used, there is less limitation in a material and a substrate and a decrease in patterning accuracy due to a solvent effect occurring from an inkjet is prevented. However, in the case of a metal oxide other than an organic semiconductor, in that a sublimination temperature of the metal oxide is very higher than 1000° C. and this damages a substrate, it is difficult to apply the OVJP process to metal oxide thin film formation.

### SUMMARY OF THE INVENTION

The present invention provides a metal oxide thin film forming method without an additional patterning process.

The present invention also provides a metal oxide printing device for realizing the metal oxide thin film forming method.

Embodiments of the present invention provide metal oxide thin film forming methods including: vaporizing a first metal oxide precursor; allowing the vaporized first metal oxide precursor to flow into a mixture chamber by using a first carrier gas; injecting the flowed first metal oxide precursor on a substrate through a micro nozzle connected to the mixture chamber to form a first metal oxide precursor layer on the substrate; and emitting electromagnetic waves to the first metal oxide precursor layer to form a first metal oxide layer.

In some embodiments, the first metal oxide precursor may be an organic metal compound that is vaporized at a higher pressure and a lower temperature than a first metal oxide including the same metal element as the first metal oxide precursor.

In other embodiments, the vaporizing of the first metal oxide precursor may include vaporizing the first metal oxide precursor under a condition that a solvent does not exist.

In still other embodiments, the forming of the first metal oxide precursor layer may include: injecting the flowed first metal oxide precursor to a first area on the substrate to form the first metal oxide precursor layer on the first area; and injecting the flowed first metal oxide precursor to a second area adjacent to the first area to form a predetermined pattern, wherein the predetermined pattern may include a first metal oxide precursor layer on the first area and a first metal oxide precursor layer on the second area connected thereto.

In even other embodiments, an amount of the first metal oxide precursor flowing into the mixture chamber may be adjusted by a flow rate of the first carrier gas.

In yet other embodiments, the metal oxide thin film forming methods may further include: vaporizing a second metal oxide precursor; allowing the vaporized second metal oxide precursor to flow into the mixture chamber by using a second carrier gas; injecting the flowed second metal oxide precursor on the substrate through the micro nozzle connected to the mixture chamber to form a second metal oxide precursor layer on the first metal oxide precursor layer or the first metal oxide layer; and forming a second metal oxide layer by emitting electromagnetic waves to the second metal oxide precursor layer.

In further embodiments, the first metal oxide layer formed using the first metal oxide precursor layer and the second metal oxide layer formed using the second metal oxide precursor layer may be stacked sequentially.

In still further embodiments, the emitting of the electromagnetic waves may be performed as soon as the first metal oxide precursor layer is formed or after the first metal oxide precursor layer is formed.

In even further embodiments, the forming of the first metal oxide layer may include changing a portion of the first metal oxide precursor layer into the first metal oxide layer by emitting electromagnetic waves to a predetermined area of the first metal oxide precursor layer.

In yet further embodiments, the electromagnetic waves may include at least one of ultraviolet ray, infrared ray, visible ray, microwave, gamma-ray, and X-ray.

In yet further embodiments, the forming of the first metal oxide layer further may include performing a post thermal treatment after electromagnetic emission.

In other embodiments of the present invention, metal oxide thin film forming methods include: vaporizing a first metal oxide precursor and a second metal oxide precursor separately; allowing the vaporized first metal oxide precursor and second metal oxide precursor to flow into a mixture chamber by using a first carrier gas and a second carrier gas, respectively, to form a mixture of the first metal oxide precursor and the second metal oxide precursor; injecting the mixture on a substrate through a micro nozzle connected to the mixture chamber to form a complex metal oxide precursor layer on the substrate; and forming a complex metal oxide layer by emitting electromagnetic waves to the complex metal oxide precursor layer.

In still other embodiments of the present invention, metal oxide thin film forming methods include: vaporizing a first metal oxide precursor and a second metal oxide precursor separately; allowing the vaporized first metal oxide precursor and second metal oxide precursor to flow into a mixture chamber by using a first carrier gas and a second carrier gas, respectively, to form a mixture of the first metal oxide precursor and the second metal oxide precursor; injecting the mixture on a substrate through a micro nozzle connected to a lower end of the mixture chamber to form a complex metal oxide precursor layer on the substrate; and forming a complex metal oxide layer by emitting electromagnetic waves to the complex metal oxide precursor layer.

In other embodiments, an amount of the first metal oxide precursor flowing into the mixture chamber and an amount of the second metal oxide precursor flowing into the mixture chamber may be adjusted by a flow rate of the first carrier gas and a flow rate of the second carrier gas, respectively; and a composition of the complex metal oxide layer may be adjusted by the amount of the first metal oxide precursor flowing into the mixture chamber and the amount of the second metal oxide precursor flowing into the mixture chamber.

In even other embodiments of the present invention, metal oxide thin film printing devices include: a first storage chamber receiving a first metal oxide precursor and including a first heater for vaporizing the first metal oxide precursor; a mixture chamber connected to the first storage chamber and into which the vaporized first metal oxide precursor flows together with a first carrier gas, the first metal oxide precursor and the first carrier gas being transferred to a micro nozzle connected to the mixture chamber; a first carrier gas valve adjusting an amount of the first metal oxide precursor flowing into the mixture chamber; the micro nozzle injecting the first metal oxide precursor; a first electromagnetic emitter emitting electromagnetic waves to change the first metal oxide precursor into a first metal oxide; a first stage where a substrate is loaded and a first metal oxide precursor layer is formed on the substrate; and a second stage where the substrate transferred from the first stage is loaded and a first metal oxide layer is formed from the first metal oxide precursor layer by emitting the electromagnetic waves on the substrate.

In other embodiments, the substrate may be a flexible substrate and the flexible substrate may be transferred from the first stage to the second stage by a roll.

In still other embodiments, the devices may further include a deposition chamber including the first storage chamber, the mixture chamber, the micro nozzle, the first electromagnetic emitter, the first stage, and the second stage in the device.

In even other embodiments, the devices may further include a second electromagnetic emitter emitting electromagnetic waves to selectively heat the first metal oxide precursor layer or the first metal oxide layer, on the second stage.

In yet other embodiments, the devices may further include: a second storage chamber receiving a second metal oxide precursor and including a second heater for vaporizing the second metal oxide precursor; and a second carrier gas valve adjusting an amount of the second metal oxide precursor flowing into the mixture chamber, wherein the mixture chamber may be connected to the second storage chamber and the vaporized second metal oxide precursor may flow into the mixture chamber together with a second carrier gas; and the micro nozzle may inject a first metal oxide precursor, a second metal oxide precursor, or a mixture thereof.

In further embodiments, the mixture chamber may mix the first metal oxide precursor and the second metal oxide precursor and the micro nozzle may inject a mixture of the first metal oxide precursor and the second metal oxide precursor.

In still further embodiments, the devices may further include a controller separately controlling the first carrier gas valve and the second carrier gas valve.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1A is a view illustrating a metal oxide thin film printing device according to an embodiment of the present invention;

FIG. 1B is a view illustrating a carrier gas supplier according to an embodiment of the present invention;

FIG. 1C is a view illustrating a metal oxide thin film printing device according to another embodiment of the present invention;

FIG. 2A is a view illustrating a metal oxide thin film printing device according to another embodiment of the present invention.

FIG. 2B is a view illustrating a metal oxide thin film printing device according to another embodiment of the present invention;

FIG. 3 is a flowchart illustrating a method of forming a metal oxide thin film according to an embodiment of the present invention;

FIGS. 4A to 4C are views illustrating a method of forming a patterned metal oxide precursor layer according to an embodiment of the present invention;

FIGS. 5A to 5C are views illustrating a patterning method according to an embodiment of the present invention;

FIG. 6 is a flowchart illustrating a method of forming a metal oxide thin film according to another embodiment of the present invention;

FIGS. 7A to 7C are sectional views illustrating a method of forming a multilayer structure where a first metal oxide layer and a second metal oxide layer are sequentially stacked according to another embodiment of the present invention;

FIG. 8 is a flowchart illustrating a method of forming a metal oxide thin film according to another embodiment of the present invention;

FIGS. 9A and 9B are sectional views illustrating a method of forming a complex metal oxide layer according to another embodiment of the present invention;

FIGS. 10A to 10C are cross-sectional views illustrating a method of fabricating a thin film transistor according to an embodiment of the inventive concept;

FIG. 11 is a graph illustrating a refractive index of each of a thin film of comparative example 1 and a thin film of example 1 according to an embodiment of the present invention;

FIG. 12 is a graph illustrating an X-ray diffraction analysis result of each of a thin film of comparative example 1 and a thin film of example 1 according to an embodiment of the present invention; and

FIG. 13 is a graph illustrating an electrical characteristic of a thin film of example 1 according to an embodiment of the present invention.

### DETAILED DESCRIPTION OF PREFERRED EMBODIMENTS

The objects, other objects, features, and advantages of the present invention are easily understood through below embodiments relating to the accompanying drawings. The present invention is not limited to embodiments described herein and may be realized in different forms. Rather, these embodiments are provided so that this disclosure will be thorough and complete, and will fully convey the scope of the present invention to those skilled in the art.

These terms are only used to distinguish one element from another element. It will also be understood that when a layer (or film) is referred to as being ‘on’ another layer or substrate, it can be directly on the other layer or substrate, or intervening layers may also be present. In the figures, the dimensions of layers and regions are exaggerated for clarity of illustration. Also, though terms like a first and a second are used to describe various members, components, regions, layers, and/or portions in various embodiments of the present invention, the members, components, regions, layers, and/or portions are not limited to these terms. These terms are used only to differentiate one member, component, region, layer, or portion from another one. Therefore, a layer referred to as a first layer in one embodiment can be referred to as a second layer in another embodiment. An embodiment described and exemplified herein includes a complementary embodiment thereof. The word ‘and/or’ means that one or more or a combination of relevant constituent elements is possible. Like reference numerals refer to like elements throughout.

Hereinafter, a metal oxide thin film forming method, a metal oxide thin film printing device, and a thin film transistor fabricating method are described in more detail with reference to the accompanying drawings.

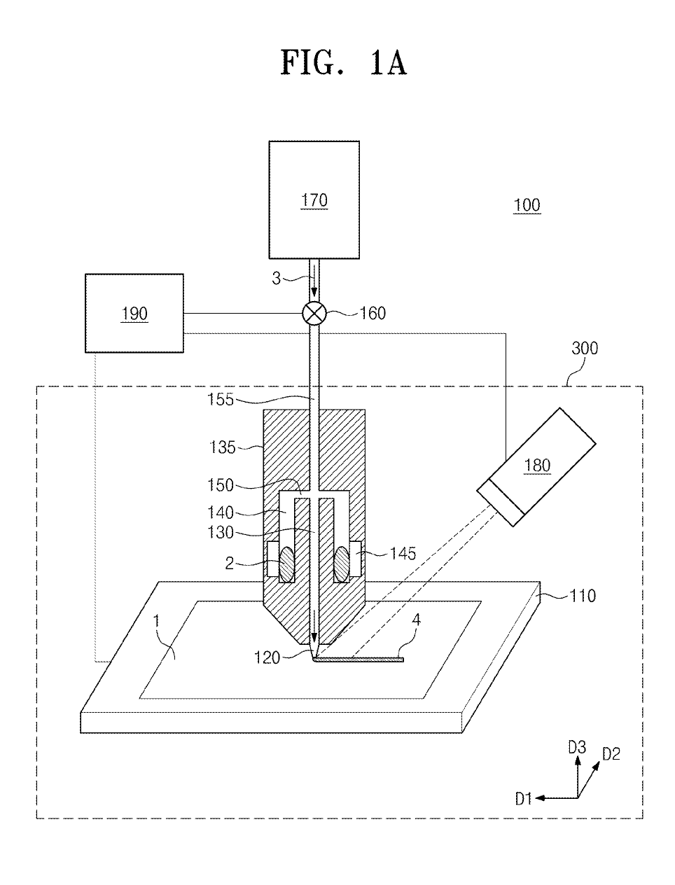

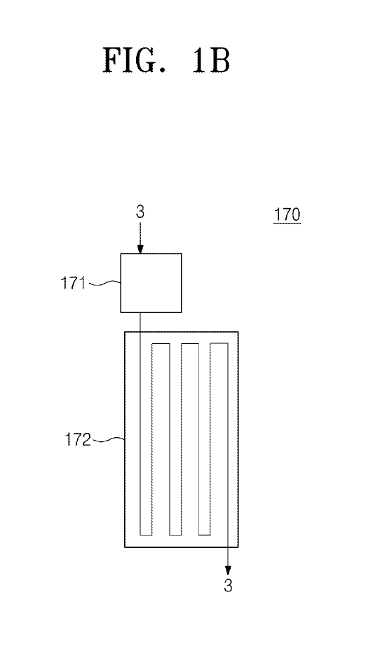

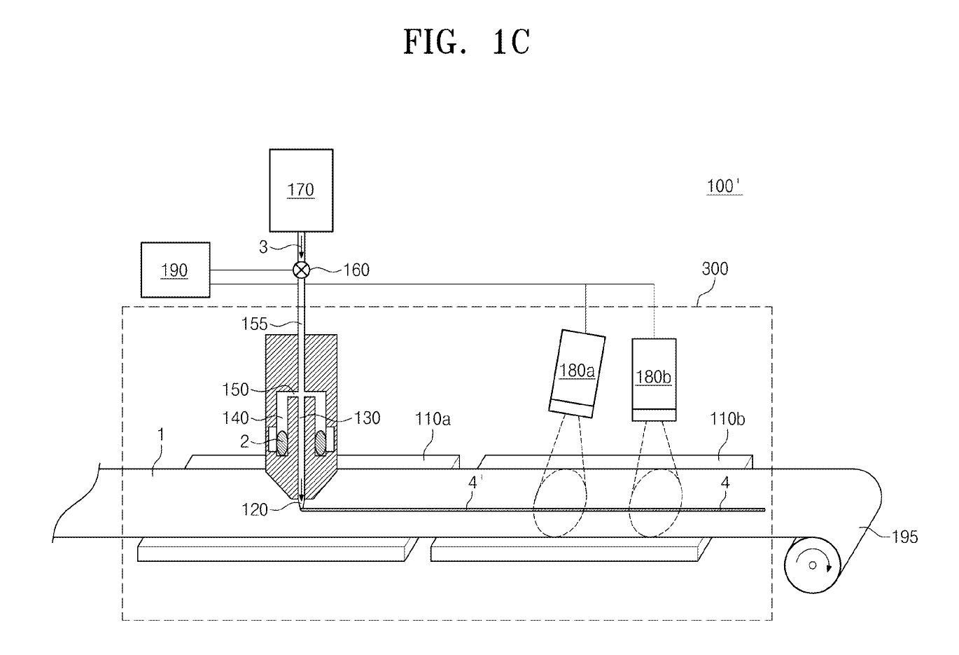

FIG. 1A is a view illustrating a metal oxide thin film printing device 100 for forming a metal oxide thin film according to an embodiment of the present invention.

Referring to FIG. 1A, the metal oxide thin film printing device 100 includes a first storage chamber 140 receiving a first metal oxide precursor 2, a mixture chamber 130 connected to the first storage chamber 140, a first carrier gas valve 160 adjusting the flow rate of a first carrier gas 3, a micro nozzle 120 injecting the first metal oxide precursor 2, an electromagnetic emitter 180 emitting electromagnetic waves to change the injected first metal oxide precursor 2 into a metal oxide, and a stage 110 loading a substrate 1. Furthermore, the metal oxide thin film printing device 100 may further include an outer cover 135 surrounding the first storage chamber 140 and the mixture chamber 130.

The first storage chamber 140 may include a first heater 145 for vaporizing the first metal oxide precursor 2. The first heater 145 may heat the first storage chamber 140 up to about 500° C. and for example, may adjust a temperature in the first storage chamber 140 to a temperature at which the first metal oxide precursor 2 is vaporized. Furthermore, the first storage chamber 140 may be formed in plurality. The first metal oxide precursor 2 may be received in each of the first storage chambers 140.

The first metal oxide precursor 2 may flow into the mixture chamber 130 together with the first carrier gas 3. The first storage chamber 140 and the mixture chamber 130 may be connected to a transfer passage 150 and the first metal oxide precursor 2 may flow into the mixture chamber 130 through the transfer passage 150. One shaft end (upper end) of the mixture chamber 130 may be connected to the first carrier gas transfer passage 155 and the first carrier gas 3 may flow into the mixture chamber 130 through the first carrier gas transfer passage 155. The first carrier gas valve 160 may be disposed on the first carrier gas transfer passage 155 and the flow rate of the first carrier gas 3 flowing into the mixture chamber 130 may be adjusted through the first carrier gas valve 160. Since the amount of the first metal oxide precursor 2 flowing into the mixture chamber 130 is adjusted by the flow rate of the first carrier gas 3, the amount of the first metal oxide precursor 2 flowing into the mixture chamber 130 may be adjusted by the first carrier gas valve 160.

Another one shaft end (lower end) of the mixture chamber 130 may be connected to the micro nozzle 120. The first metal oxide precursor 2 may transfer to the micro nozzle 120 by the first carrier gas 3 along the mixture chamber 130 and may be jet-injected on the substrate 1 through the micro nozzle 120. The micro nozzle 120 may include a third heater (not shown). The third heater may heat a temperature in the micro nozzle 120 to a temperature identical to or higher than a temperature in the first storage chamber 140. Thus, since the first metal oxide precursor 2 cools as moving in the mixture chamber 130, it is possible to prevent the first metal oxide precursor 2 from being condensed in the micro nozzle 120. The diameter of the micro nozzle 120 may be changed according to the line width of the first metal oxide precursor layer or the first metal oxide layer 4 to be formed.

The electromagnetic emitter 180 may be disposed spaced apart from the outer cover 135 and the micron nozzle 120 and may emit electromagnetic waves for changing the injected first metal oxide precursor 2 into a first metal oxide. The electromagnetic waves may include at least one of UV, IR, visible ray, microwave, gamma-ray, and X-ray. The electromagnetic emitter 180 may include a lamp type large-sized light source or a direct light source such as LED or laser.

The stage 110 may be disposed below the micro nozzle 120 and the substrate 1 may be loaded on the stage 110. The substrate 1 may be spaced a predetermined distance from the micro nozzle 120 and may be disposed between the micro nozzle 120 and the stage 110. A first metal oxide precursor layer (not shown) formed from the injected first metal oxide precursor 2 or a first metal oxide layer 4 formed from the first metal oxide precursor layer as electromagnetic waves are emitted may be disposed on the substrate 1.

The stage 110 may selectively transfer in a first direction D1, a second direction D2 intersecting the first direction D1, or a third direction D3 perpendicular to the first direction D1 and the second direction D2. Accordingly, a pattern form of the first metal oxide layer 4 formed on the substrate 1 may be determined A pattern formation using the first metal oxide layer 4 will be described later.

The metal oxide thin film printing device 100 may include a carrier gas supplier 170 connected to the first carrier gas transfer passage 155. The carrier gas supplier 170 may introduce the first carrier gas 3 into the mixture chamber 130.

FIG. 1B is a view illustrating the carrier gas supplier 170 according to an embodiment of the present invention.

Referring to FIG. 1B, the carrier gas supplier 170 may include a flowmeter 171 and a preheater 172. The first carrier gas 3 may pass through the flowmeter 171 and the preheater 172 and may then flow into the first carrier gas transfer passage 155. The flowmeter 171 may monitor the flow rate of the first carrier gas 3 and the preheater 172 may heat the first carrier gas 3 to an appropriate temperature.

The metal oxide thin film printing device 100 may include a controller 190 for controlling the opening/closing of the first carrier gas valve 160. For example, the controller 190 may control the first carrier gas valve 160 in response to a digital signal from a pulse generator. Thereby, the first carrier gas valve 160 may be controlled at high speed.

The controller 190 may control the first heater 145 in the first storage chamber 140 and the third heater (not shown) in the micro nozzle 120, thereby controlling a temperature of the first storage chamber 140 and a temperature in the micro nozzle 120. Additionally, in order to allow a temperature of the first storage chamber 140 and a temperature in the micro nozzle 120 to be different from each other, the first heater 145 and the third heater may be controlled separately.

The controller 190 may control the electromagnetic emitter 180 and thus, may control the frequency, intensity, emitting time, and emitting area of electromagnetic waves emitted from the electromagnetic emitter 180.

The controller 190 may control the stage 110 and thus may control a moving direction of the stage 110.

The metal oxide thin film printing device 100 may further include a deposition chamber 300. The first storage chamber 140, the mixture chamber 130, the micro nozzle 120, the electromagnetic emitter 180, and the stage 110 may be disposed in the deposition chamber 300. That is, the first metal oxide precursor layer and/or the first metal oxide layer 4 may be formed on the substrate 1 in the deposition chamber 300. The deposition chamber 300 may provide an environment for forming the first metal oxide precursor layer and/or the first metal oxide layer 4 by separating the inner space of the deposition chamber 300 from an external environment in order for disconnection. Moreover, since the first metal oxide precursor 2 is easily vaporized, the formation of the first metal oxide precursor layer and/or the first metal oxide layer 4 may be possible under a relatively low deposition condition. The relatively low deposition condition may be a high pressure close to atmospheric pressure and a low temperature of less than about 200° C. It is difficult for the electromagnetic emitter 180 to be disposed under the vacuum or high temperature condition. Moreover, as described above, since the metal oxide thin film printing device 100 forms a thin film under the relatively low deposition condition, the electromagnetic emitter 180 may be disposed in the deposition chamber 300. Thereby, the electromagnetic emitter 180 may effectively perform the injection of the first metal oxide precursor 2 and the changing of the first metal oxide precursor 2 in one device in conjunction with the micro nozzle 120.

The deposition chamber 300 may include a vacuum pump (not shown) and may adjust a pressure in the inner space of the deposition chamber 300 by using the vacuum pump. Thereby, a pressure condition for the vaporization and deposition of the first metal oxide precursor 2, for example, a low vacuum condition of about 10 mmHg to about 760 mmHg, may be formed.

FIG. 1C is a view illustrating a metal oxide thin film printing device 100′ for forming a metal oxide thin film according to another embodiment of the present invention. Herein, only the configuration that is distinguished from that of the metal oxide thin film printing device 100 described with reference to FIG. 1A will be described.

Referring to FIG. 1C, a roll-to-roll process of the metal oxide thin film printing device 100′ is shown as an application example. In more detail, the metal oxide thin film printing device 100′ may further include a first stage 110a loading the substrate 1, a second stage 110b loading the transferred substrate 1, and a first electromagnetic emitter 180a emitting electromagnetic waves on the substrate 1 loaded to the second stage 110b. Furthermore, the substrate 1 may be a flexible substrate and in this case, the metal oxide thin film printing device 100′ may further include a roll 195 for transferring the flexible substrate from the first stage 110a to the second stage 110b. Thereby, a roll-to-roll process, in which the deposition of a first metal oxide precursor and changing from a first metal oxide precursor to a first metal oxide are continuously and sequentially performed, may be realized.

Unlike the above-mentioned metal oxide thin film printing device 100, the first stage 110a and the second stage 110b may be selectively transferred in the second direction D2 or the third direction D3. Additionally, the first stage 110a and the second stage 110b may be integrated. The substrate 1 may be transferred in the first direction D1 by the roll 195. Accordingly, a pattern form of the first metal oxide layer 4 formed on the substrate 1 may be determined Or, as the micro nozzle 120 injecting the first metal oxide precursor is selectively transferred in the first direction D1, the second direction D2, and the third direction D3, the pattern form of the first metal oxide layer 4 may be determined and the present invention is not limited thereto.

As the first metal oxide precursor is injected on the loaded substrate 1, a first metal oxide precursor layer 4′ may be formed on the first stage 110a. Then, the substrate 1 including the formed first metal oxide precursor layer 4′ may be transferred on the second stage 110b.

As electromagnetic waves are emitted on the loaded substrate 1, a first metal oxide layer 4 may be formed from the first metal oxide precursor layer 4′, on the second stage 110b. The electromagnetic waves may be emitted through the first electromagnetic emitter 180a.

The first electromagnetic emitter 180a may include a light source emitting electromagnetic waves onto a large area of the substrate 1. In this case, a pattern of the first metal oxide precursor layer 4′ formed on the first stage 110a may change into a pattern of the first metal oxide layer 4 collectively. Thereby, process productivity may be improved.

The metal oxide thin film printing device 100′ may further include a second electromagnetic emitter 180b emitting electromagnetic waves to selectively heat the first metal oxide precursor layer 4′ or the first metal oxide layer 4, on the second stage 110b. In more detail, the second electromagnetic emitter 180b is disposed at the front end than the first electromagnetic emitter 180a, so that it may selectively heat the first metal oxide precursor layer 4′. Or, the second electromagnetic emitter 180b is disposed at the rear end than the first electromagnetic emitter 180a, so that it may selectively heat the first metal oxide layer 4. Then, the conversion rate from the first metal oxide precursor layer 4′ to the first metal oxide layer 4 may be further improved. The second electromagnetic emitter 180b may emit electromagnetic waves onto a large area of the substrate 1 like the first electromagnetic emitter 180a. The electromagnetic waves emitted from the second electromagnetic emitter 180b may be a visible or infrared light for selectively raising a temperature of the first metal oxide precursor layer 4′ and/or the first metal oxide layer 4 on the substrate 1. The second electromagnetic emitter 180b may include a flash lamp or a pulse laser.

The metal oxide thin film printing device 100′ may further include a deposition chamber 300. The first storage chamber 140, the mixture chamber 130, the micro nozzle 120, the first electromagnetic emitter 180a, the second electromagnetic emitter 180b, the first stage 110a, and the second stage 110b may be disposed in the deposition chamber 300. The deposition chamber 300 of the metal oxide thin film printing device 100′ may be identical to that of the metal oxide thin film printing device 100 described with reference to FIG. 1A. Since the metal oxide thin film printing device 100′ forms a thin film under a relatively low deposition condition, the first electromagnetic emitter 180a and the second electromagnetic emitter 180b may be disposed in the deposition chamber 300. Thus, it is possible to realize a continuous roll-to-roll process performing the deposition and changing of the first metal oxide precursor 2 in one device.

Moreover, as described above, since the metal oxide thin film printing device 100′ forms a thin film under the relatively low deposition condition, the deposition of a first metal oxide precursor and the changing from the first metal oxide precursor to a first metal oxide may be performed in separate stages. Thus, the pattern of the first metal oxide precursor layer 4′ may change into the pattern of the first metal oxide layer 4 collectively due to the large area electromagnetic emission on the second stage 110b.

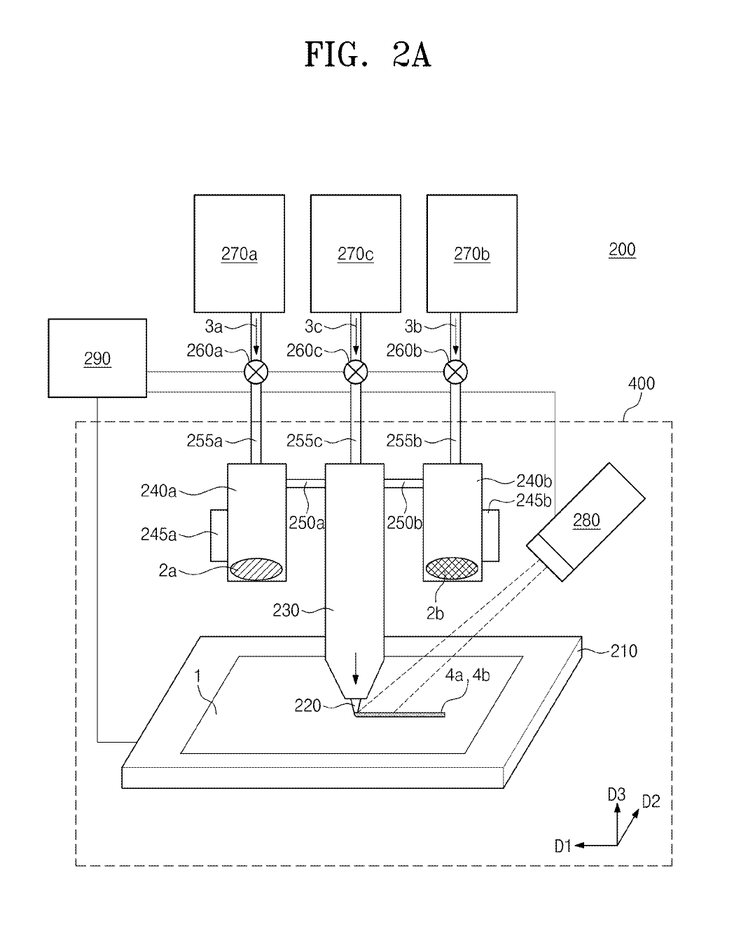

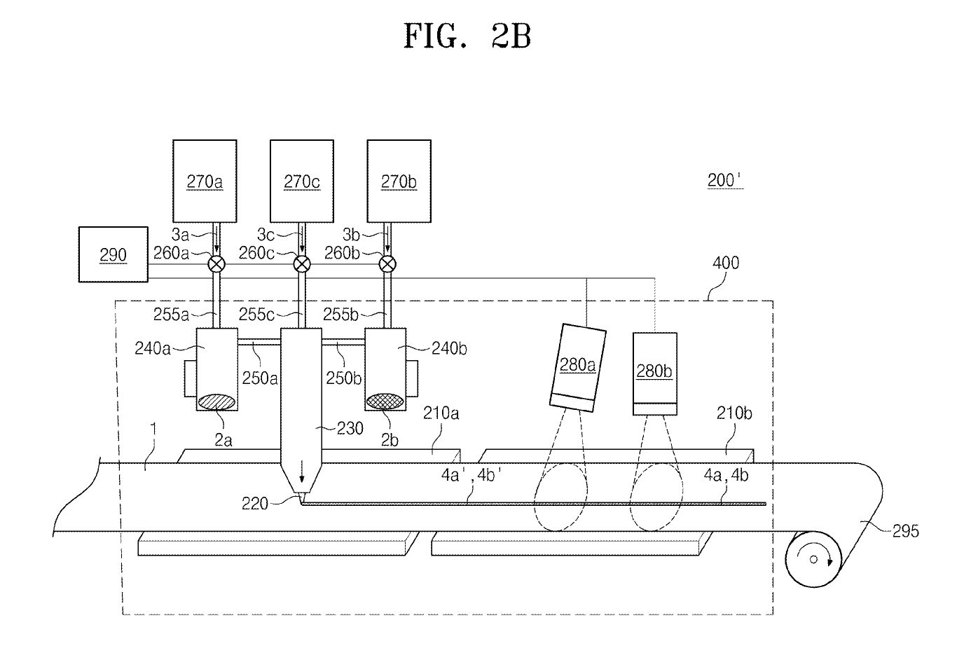

FIG. 2A is a view illustrating a metal oxide thin film printing device 200 for forming a metal oxide thin film according to another embodiment of the present invention.

Referring to FIG. 2A, the metal oxide thin film printing device 200 includes a first storage chamber 240a receiving a first metal oxide precursor 2a, a second storage chamber 240b receiving a second metal oxide precursor 2b, a mixture chamber 230 connected to the first storage chamber 240a and the second storage chamber 240b, a first carrier gas valve 260a adjusting the flow rate of a first carrier gas 3a, a second carrier gas valve 260b adjusting the flow rate of a second carrier gas 3b, a micro nozzle 220 injecting the first and second metal oxide precursors 2a and 2b, an electromagnetic emitter 280 emitting electromagnetic waves to change the injected first and second metal oxide precursors 2a and 2b into a metal oxide, and a stage 210 loading a substrate 1. The first and second metal oxide precursors 2a and 2b may include the first metal oxide precursor 2a, the second metal oxide precursor 2b, and a mixture thereof. The metal oxide may include a first metal oxide formed using the first metal oxide precursor 2a, a second metal oxide formed using the second metal oxide precursor 2b, or a complex metal oxide using a mixture of the first metal oxide precursor 2a and the second metal oxide precursor 2b.

The first storage chamber 240a may include a first heater 245a for vaporizing the first metal oxide precursor 2a and the second storage chamber 240b may include a second heater 245b for vaporizing the second metal oxide precursor 2b. The first heater 245a and the second heater 245b may heat respective temperatures of the first storage chamber 240a and the second storage chamber 240b to about 500° C. For example, the first heater 245a may adjust a temperature in the first storage chamber 240a to a temperature at which the first metal oxide precursor 2a is vaporized and the second heater 245b may adjust a temperature in the second storage chamber 240b to a temperature at which the second metal oxide precursor 2b is vaporized. The first storage chamber 240a may be connected to a first carrier gas transfer passage 255a and the second first storage chamber 240b may be connected to a second carrier gas transfer passage 255b.

The vaporized first metal oxide precursor 2a may flow into the mixture chamber 230 together with a first carrier gas 3a and the vaporized second metal oxide precursor 2b may flow into the mixture chamber 230 together with a second carrier gas 3b. The first storage chamber 240a and the mixture chamber 230 may be connected to a first transfer passage 250a and the second storage chamber 240b and the mixture chamber 230 may be connected to a second transfer passage 250b. The first carrier gas 3a may flow into the first storage chamber 240a through the first carrier gas transfer passage 255a and the flowed first carrier gas 3a may flow into the mixture chamber 230 together with the first metal oxide precursor 2a vaporized in the first storage chamber 240a through the first transfer passage 250a. The second carrier gas 3b may flow into the second storage chamber 240b through the second carrier gas transfer passage 255b and the flowed second carrier gas 3b may flow into the mixture chamber 230 together with the second metal oxide precursor 2b vaporized in the second storage chamber 240b through the second transfer passage 250b.

The first carrier gas valve 260a may be disposed on the first carrier gas transfer passage 255a and the second carrier gas valve 260b may be disposed on the second carrier gas transfer passage 255b. The flow rate of the first carrier gas 3a flowing into the first storage chamber 240a and the mixture chamber 230 may be adjusted through the first carrier gas valve 260a and the flow rate of the second carrier gas 3a flowing into the second storage chamber 240b and the mixture chamber 230 may be adjusted through the second carrier gas valve 260b. For example, since the amount of the first metal oxide precursor 2a flowing into the mixture chamber 230 is adjusted by the flow rate of the first carrier gas 3a, the amount of the first metal oxide precursor 2a flowing into the mixture chamber 230 may be adjusted by the first carrier gas valve 260a. By the same principle, the amount of the second metal oxide precursor 2b flowing into the mixture chamber 230 may be adjusted by using the second carrier gas valve 260b.

One shaft end (upper end) of the mixture chamber 230 may be connected to a third carrier gas transfer passage 255c and a third carrier gas 3c may flow into the mixture chamber 230 through the third carrier gas transfer passage 255c. The third carrier gas valve 260c may be disposed on the third carrier gas transfer passage 255c and the flow rate of the third carrier gas 3c flowing into the mixture chamber 230 may be adjusted through the third carrier gas valve 260c. The third carrier gas 3c may transfer along the mixture chamber 230 together with the metal oxide precursors 2a and 2b flowing into the mixture chamber 230. For example, by adjusting the flow rate of the third carrier gas 3c, the flow rates of the metal oxide precursors 2a and 2b in the mixture chamber 230 and the injection rate of the micro nozzle 220 may be adjusted.

Another one shaft end (lower end) of the mixture chamber 230 may be connected to the micro nozzle 220. The metal oxide precursors 2a and 2b may transfer to the micro nozzle 220 along the mixture chamber 230 by the third carrier gas 3c and may be jet-injected on the substrate 1 through the micro nozzle 220. In more detail, by the flow rate of the third carrier gas 3a controlled by the first carrier gas valve 260a and the flow rate of the second carrier gas 3b controlled by the second carrier gas valve 260b, the metal oxide precursors 2a and 2b injected through the micro nozzle 220 may include the first metal oxide precursor 2a, the second metal oxide precursor 2b, or a mixture thereof. For example, when the first carrier gas valve 260a is opened and the second carrier gas valve 260b is closed, the first metal oxide precursor 2a may be injected through the micro nozzle 220. For example, when the first carrier gas valve 260a is opened and the second carrier gas valve 260b is opened, a mixture of the first metal oxide precursor 2a and the second metal oxide precursor 2b may be injected through the micro nozzle 220.

The micro nozzle 220 may include a third heater (not shown). The third heater may heat a temperature in the micro nozzle 220 to a temperature identical to or higher than a temperature in the first storage chamber 240a or a temperature in the second storage chamber 240b. Thus, since the metal oxide precursors 2a and 2b cool through the mixture chamber 230, it is possible to prevent the metal oxide precursors 2a and 2b from being condensed in the micro nozzle 220. The diameter of the micro nozzle 220 may be changed according to the line width of a metal oxide precursor layer or the metal oxide layers 4a and 4b to be formed.

The electromagnetic emitter 280 may be disposed spaced apart from the mixture chamber 230 and the micro nozzle 220 and may emit electromagnetic waves for changing the injected metal oxide precursors 2a and 2b into a metal oxide. This may be the same as described through FIG. 1A.

The stage 210 may be disposed below the micro nozzle 220 and the substrate 1 may be loaded on the stage 210. The substrate 1 may be spaced a predetermined distance from the micro nozzle 220 and may be disposed between the micro nozzle 220 and the stage 210. A metal oxide precursor layer formed from the injected metal oxide precursors 2a and 2b or the metal oxide layers 4a and 4b formed from the metal oxide precursor layer as electromagnetic waves are emitted may be disposed on the substrate 1. The metal oxide precursor layer may include a first metal oxide precursor layer formed from the first metal oxide precursor 2a, a second metal oxide precursor layer formed from the second metal oxide precursor 2b, and a complex metal oxide precursor layer formed from a mixture of the first metal oxide precursor 2a and the second metal oxide precursor 2b. The metal oxide layers 4a and 4b may include a first metal oxide layer 4a formed from the first metal oxide precursor layer, a second metal oxide layer 4b formed from the second metal oxide precursor layer, and a complex metal oxide layer formed from the complex metal oxide precursor layer.

The stage 210 may transfer selectively in the first direction D1, the second direction D2, or the third direction D3. Accordingly, a pattern form of the metal oxide layers 4a and 4b formed on the substrate 1 may be determined

The metal oxide thin film printing device 200 may include a first carrier gas supplier 270a connected to the first carrier gas transfer passage 255a, a second carrier gas supplier 270b connected to the second carrier gas transfer passage 255b, and a third carrier gas supplier 270c connected to the third carrier gas transfer passage 255c. Each of the first carrier gas supplier 270a, the second carrier gas supplier 270b, and the third carrier gas supplier 270c may be identical to the carrier gas supplier 170 described with reference to FIGS. 1A and 1B.

The metal oxide thin film printing device 200 may include a controller 290 for controlling the opening/closing of the first carrier gas valve 260a, the second carrier gas valve 260b, and the third carrier gas valve 260c. For example, the controller 290 may separately control the first carrier gas valve 260a, the second carrier gas valve 260b, and the third carrier gas valve 260c and accordingly, a composition of the metal oxide precursors 2a and 2b injected through the micro nozzle 220 may be controlled. As described above, the controller 290 may open the first carrier gas valve 260a to allow the first metal oxide precursor 2a to be injected or may open both the first carrier gas valve 260a and the second carrier gas valve 260b to allow a mixture of the first metal oxide precursor 2a and the second metal oxide precursor 2b to be injected. Furthermore, the flow rate of the first carrier gas 3a and the second carrier gas 3b are controlled by controlling the first carrier gas valve 260a and the second carrier gas valve 260b. As a result, the composition of a mixture of the first metal oxide precursor 2a and the second metal oxide precursor 2b may be controlled. For example, the controller 290 may control the first carrier gas valve 260a, the second carrier gas valve 260b, and the third carrier gas valve 260c through a digital signal generated by a pulse generator.

The controller 290 may separately control the first heater 145 in the first storage chamber 245a, the second heater 245b in the second storage chamber 240b, and the third heater (not shown) in the micro nozzle 220. This may be the same as described through FIG. 1A.

The controller 290 may control the electromagnetic emitter 280 and this may be the same as described through FIG. 1A.

The controller 290 may control the stage 210 and this may be the same as described through FIG. 1A.

The metal oxide thin film printing device 200 may further include a deposition chamber 400 and this may be the same as described through FIG. 1A. The first storage chamber 240a, the second storage chamber 240b, the mixture chamber 230, the micro nozzle 220, the electromagnetic emitter 280, and the stage 210 may be disposed in the deposition chamber 400. Furthermore, the deposition chamber 400 may include a vacuum pump (not shown) for adjusting a pressure in the inner space of the deposition chamber 400.

FIG. 2B is a view illustrating a metal oxide thin film printing device 200′ for forming a metal oxide thin film according to another embodiment of the present invention. Herein, only the configuration that is distinguished from that of the metal oxide thin film printing device 200 described with reference to FIG. 2A will be described.

Referring to FIG. 2B, a roll-to-roll process of the metal oxide thin film printing device 200′ is shown as an application example. In more detail, the metal oxide thin film printing device 200′ may further include a first stage 210a loading the substrate 1, a second stage 210b loading the transferred substrate 1, and a first electromagnetic emitter 280a emitting electromagnetic waves on the substrate 1 loaded to the second stage 210b. Furthermore, the substrate 1 may be a flexible substrate and in this case, the metal oxide thin film printing device 200′ may further include a roll 295 for transferring the flexible substrate from the first stage 210a to the second stage 210b. Thereby, a roll-to-roll process, in which the deposition of a metal oxide precursor and changing from a metal oxide precursor to a metal oxide are continuously and sequentially performed, may be realized. The first stage 210a, the second stage 210b, the first electromagnetic emitter 280a, and the roll 295 are identical to those of the metal oxide thin film printing device 100′ described with reference to FIG. 1C.

As the metal oxide precursor is injected on the loaded substrate 1, metal oxide precursor layers 4a′ and 4b′ may be formed on the first stage 210a. Then, the substrate 1 including the formed metal oxide precursor layers 4a′ and 4b′ may be transferred on the second stage 210b. The metal oxide precursor layers 4a′ and 4b′ may include a first metal oxide precursor layer 4a′ formed from the first metal oxide precursor 2a, a second metal oxide precursor layer 4b′ formed from the second metal oxide precursor 2b, and a complex metal oxide precursor layer formed from a mixture of the first metal oxide precursor 2a and the second metal oxide precursor 2b.

As electromagnetic waves are emitted on the loaded substrate 1, metal oxide layers 4a and 4b may be formed from the metal oxide precursor layers 4a′ and 4b′, on the second stage 210b. The electromagnetic waves may be emitted through the first electromagnetic emitter 280a. The metal oxide layers 4a and 4b may include a first metal oxide layer 4a formed from the first metal oxide precursor layer 4a′, a second metal oxide layer 4b formed from the second metal oxide precursor layer 4b′, and a complex metal oxide layer formed from the complex metal oxide precursor layer.

The metal oxide thin film printing device 200′ may further include a second electromagnetic emitter 280b emitting electromagnetic waves to selectively heat the metal oxide precursor layers 4a′ and 4b′ or the metal oxide layers 4a and 4b, on the second stage 210b. The second electromagnetic emitter 280b may be identical to that of the metal oxide thin film printing device 100′ described with reference to FIG. 1C.

The metal oxide thin film printing device 200′ may further include a deposition chamber 400. The first storage chamber 240a, the second storage chamber 240b, the mixture chamber 230, the micro nozzle 220, the first electromagnetic emitter 280a, the second electromagnetic emitter 280b, the first stage 210a, and the second stage 210b may be disposed in the deposition chamber 400. The deposition chamber 400 may be identical to that of the metal oxide thin film printing device 200 described with reference to FIG. 2A. Since the metal oxide thin film printing device 400′ forms a thin film under a relatively low deposition condition, the first electromagnetic emitter 280a and the second electromagnetic emitter 280b may be disposed in the deposition chamber 400. Thus, it is possible to realize a continuous roll-to-roll process performing the deposition and changing of the metal oxide precursors 2a and 2b in one device.

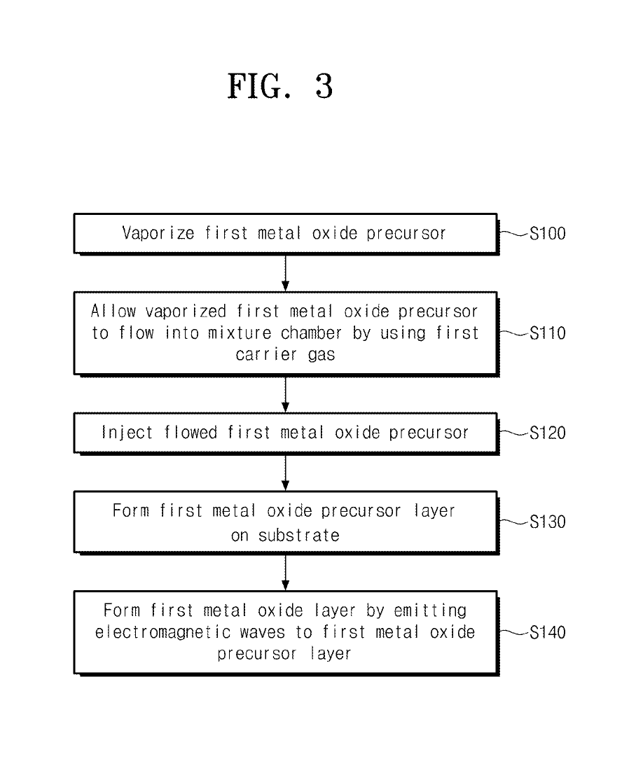

FIG. 3 is a flowchart illustrating a method of forming a metal oxide thin film according to an embodiment of the present invention.

Referring to FIGS. 1A and 3, the first metal oxide precursor 2 may be vaporized in operation S100. The first metal oxide precursor 2 is a material that changes into a first metal oxide when electromagnetic waves such as UV rays are applied and in more detail, may be an organic metal compound that is vaporized at a higher pressure and a lower temperature than the first metal oxide. Herein, the first metal oxide may be a metal oxide including the same element as the first metal oxide precursor 2. In general in order to vaporize a metal oxide, a high vacuum condition of less than about 10 mmHg and a high temperature condition of more than about 1000° C. are required. Accordingly, when vapor jet printing is performed by directly using the metal oxide, a substrate or a thin film may be damaged due to a high temperature of the injected metal oxide. However, in order to vaporize an organic metal compound including C, H, and O in a molecule, a low vacuum condition of about 10 mmHg to about 760 mmHg and a low temperature of less than about 400° C. are required in addition to a high vacuum condition of less than about 10 mmHg Accordingly, the first metal oxide precursor 2 may be vaporized at higher pressure and a lower temperature compared to a case that a first metal oxide is vaporized directly. Additionally, in relation to vapor jet printing, since a temperature of the injected first metal oxide precursor 2 is a relatively low temperature, this may not damage a substrate or a thin film.

For example, the first metal oxide precursor 2 may be zinc acetylacetonate and when UV rays are emitted on the zinc acetylacetonate, may change to a zinc oxide (ZnO).

The first metal oxide precursor 2 may be received in the first storage chamber 140 and may be heated by the first heater 145 in the first storage chamber 140. When the first metal oxide precursor 2 is heated higher than its sublimination temperature, it may be vaporized in the first storage chamber 140.

Vaporizing the first metal oxide precursor 2 may include vaporizing the first metal oxide precursor 2 under the condition that a solvent does not exist. That is, the first metal oxide precursor 2 in a solution state having a solvent added is not received in the first storage chamber 140. That is, only the first metal oxide precursor 2 may be received in the first storage chamber 140 without a solvent. When the first metal oxide precursor 2 is vaporized without an additional solvent, an additional impurity may not be included in forming a first metal oxide layer 4 described later. Additionally, during a vapor jet printing process, as injected droplets are dried, a coffee stain phenomenon that a pattern having a border thicker than the center is formed may occur. However, since there is no additional solvent, the coffee stain phenomenon may be prevented.

Referring to FIGS. 1A and 3, the vaporized first metal oxide precursor 2 may flow into the mixture chamber 130 by using the first carrier gas 3 in operation S110. The vaporized first metal oxide precursor 2 may flow into the mixture chamber 130 through a transfer passage 150 disposed between the first storage chamber 140 and the mixture chamber 130. At this point, the first carrier gas 3 may flow into the mixture chamber 130 and transfers the first metal oxide precursor 2 as flowing. In such a principle, the amount of the first metal oxide precursor 2 flowing into the mixture chamber 130 may be adjusted by the flow rate of the first carrier gas 3. Since the amount of the first metal oxide precursor 2 flowing into the mixture chamber 130 corresponds to the injection amount of the first metal oxide precursor described later and the deposition amount of the first metal oxide precursor 2 on the substrate 1, the injection amount and the deposition amount may be adjusted through the flow rate of the first carrier gas 3. Additionally, the vaporization amount of the first metal oxide precursor 2 is increased by raising a temperature in the first storage chamber 140 or lowering a process pressure, so that the amount of the flowed first metal oxide precursor 2 may be increased.

The first carrier gas 3 may be inert gas and for example, may include at least one of helium, nitrogen, and argon.

Referring to FIGS. 1A and 3, the flowed first metal oxide precursor 2 may be injected on the substrate 1 through the micro nozzle 120 connected to a lower end of the mixture chamber 130 in operation S120. Then, a first metal oxide precursor layer may be formed from the first metal oxide precursor 2 injected on the substrate 1 in operation S130.

The first metal oxide precursor 2 may transfer to the micro nozzle 120 by the first carrier gas 3 along the mixture chamber 130. Then, the first metal oxide precursor 2 may be jet-injected on the substrate 1 through the micro nozzle 120 by the first carrier gas 3. The micro nozzle 120 may include a third heater (not shown) and may prevent the first metal oxide precursor 2 from being condensed by using the third heater.

A first metal oxide precursor layer may be formed on the substrate 1 as the first metal oxide precursor 2 injected from the micro nozzle 120 is cooled and condensed. The first metal oxide precursor layer may be a zinc acetylacetonate layer. The first metal oxide precursor layer may be formed on the substrate 1 as the first metal oxide precursor 2 cools by itself without an additional thermal treatment. As described above, since a sublimination temperature of the first metal oxide precursor 2 is considerably lower than a sublimination temperature of the first metal oxide, the first metal oxide precursor layer may be formed without thermally damaging the substrate 1.

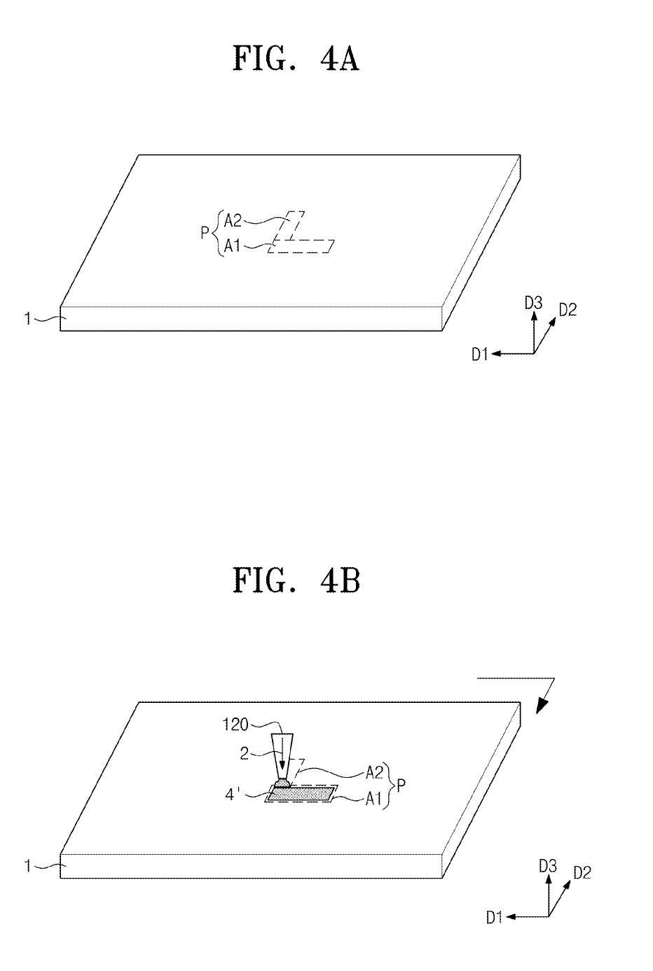

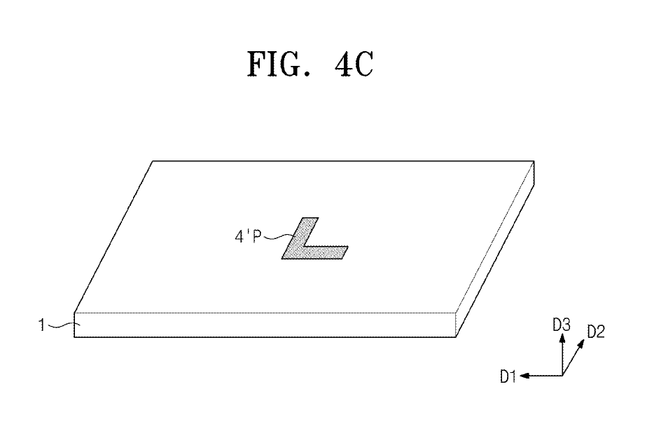

FIGS. 4A to 4C are views illustrating a method of forming a patterned first metal oxide precursor layer.

Referring to FIG. 4A, a pattern area P of a first metal oxide precursor layer to be formed may be defined. The pattern area P may include the first area A1 and the second area A2. For example, the pattern area P may be defined in an L shape on the substrate 1. The pattern area P includes the first area A1 extending in the first direction D1 and the second area A2 extending in the second direction D2 as contacting the first area A1.

Referring to FIG. 4B, a first metal oxide precursor layer 4′ may be sequentially form on each of the first area A1 and the second area A2. As the first metal oxide precursor 2 injected from the micro nozzle 120 is deposited on the surface of the substrate 1, the first metal oxide precursor layer 4′ may be formed. For example, the first metal oxide precursor layer 4′ may be formed in the first area A1 in the first direction D1 as the substrate 1 transfers in a direction opposite to the first direction D1. Then, the first metal oxide precursor layer 4′ may be formed in the second area A2 in the second direction D2 as the substrate 1 transfers in a direction opposite to the second direction D2.

Referring to FIG. 4C, a predetermined pattern 4′P may be formed on the pattern area P. For example, referring to FIG. 4B again, the predetermined pattern 4′P may have a form in which the first metal oxide precursor layer 4′ on the first area A1 and the first metal oxide precursor layer 4′ on the second area A2 are connected to each other.

In relation to a metal oxide thin film forming method according to an embodiment of the present invention, since the first metal oxide precursor 2 is injected from the micro nozzle 120, a first metal oxide precursor layer may be locally formed on the substrate 1. Accordingly, without an additional patterning process, a patterned first metal oxide precursor layer may be formed and a patterned first metal oxide layer may be formed therefrom.

Referring to FIGS. 1A and 3, a first metal oxide layer 4 may be formed in operation S140 by emitting electromagnetic waves on the first metal oxide precursor layer. When electromagnetic waves are emitted on the first metal oxide precursor layer, as C and H therein leave, the first metal oxide layer 4 may be formed. For example, when the first metal oxide precursor layer is a zinc acetylacetonate layer, as shown in the following reaction formula, a ZnO layer may be formed by emitting UV rays on the zinc acetylacetonate layer.

Zn(C₅H₇O₂)₂(S).H₂O→ZnO(S)+2C₅H₈O₂(g) [Reaction Formula 1]

The electromagnetic waves may include at least one of UV, IR, visible ray, microwave, gamma-ray, and X-ray and may be appropriately selected by those skilled in the art according to the type of the first metal oxide precursor 2.

The electromagnetic waves may be emitted as soon as the first metal oxide precursor layer is formed or after the first metal oxide precursor layer is formed. For example, when the electromagnetic waves are emitted as soon as the first metal oxide precursor layer is formed, it may change to the first metal oxide layer 4 as the first metal oxide precursor layer is deposited. For another example, when the electromagnetic waves are emitted after the first metal oxide precursor layer is formed, the electromagnetic waves may be emitted as post processing after the first metal oxide precursor layer is formed in a desired area. In this case, among multilayered metal oxide precursors stacked on the substrate 1, only one metal oxide precursor layer may selectively change to a metal oxide layer. Or, from the plane viewpoint, only a partial area of the formed metal oxide precursor layer may change to a metal oxide layer. The latter case will be described in more detail below.

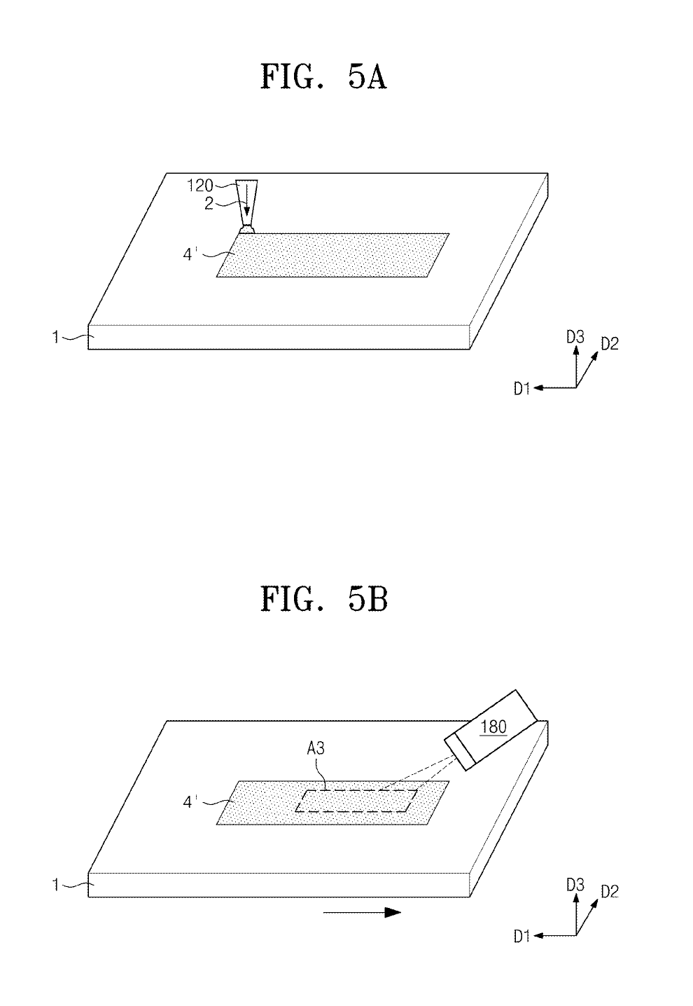

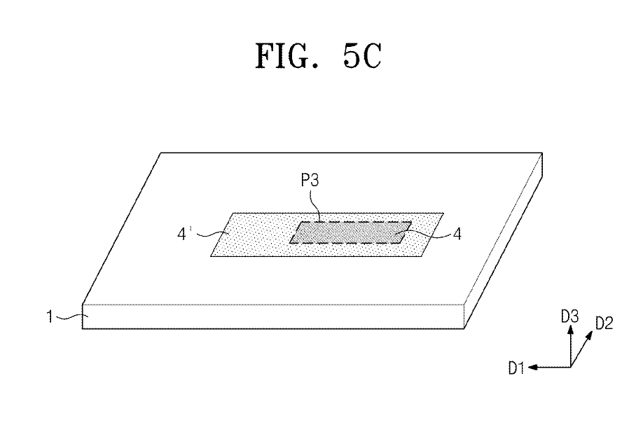

FIGS. 5A to 5C are views illustrating a patterning method of changing only a partial area of a formed metal oxide precursor layer.

Referring to FIG. 5A, a first metal oxide precursor layer 4′ may be formed on a substrate 1. As the first metal oxide precursor 2 injected from the micro nozzle 120 is deposited on the surface of the substrate 1, the first metal oxide precursor layer 4′ may be formed.

Referring to FIG. 5B, after the first metal oxide precursor layer 4′ is formed, electromagnetic waves may be emitted on a predetermined area A3 of the first metal oxide precursor layer 4′. The predetermined area A3 may be defined according to a desired pattern form of a first metal oxide layer 4. The electromagnetic waves may be emitted through an electromagnetic emitter 180. For example, when electromagnetic waves are emitted on the predetermined area A3 extending in a first direction D1, they may be emitted as the substrate 1 transfers in a direction opposite to the first direction D1.

Referring to FIG. 5C, a pattern P3 corresponding to the predetermined area A3 may be formed. When electromagnetic waves are emitted on the predetermined area A3, the pattern P3 may be obtained as the first metal oxide precursor layer 4′ on the predetermined area A3 changes to the first metal oxide layer 4. Since the first metal oxide precursor layer 4′ in an area where electromagnetic waves are not emitted is maintained as it is, another area other than the predetermined area A3 may be an unchanged first metal oxide precursor layer 4′.

A metal oxide thin film forming method according to an embodiment of the present invention may form a desired metal oxide pattern by simply post-processing electromagnetic waves. Accordingly, without additionally performing an etching process such as a photolithography process using a mask, a complex pattern may be formed effectively.

The forming of the first metal oxide layer 4 may further include performing a post thermal treatment after electromagnetic waves are emitted. Then, the conversion rate from the first metal oxide precursor layer to the first metal oxide layer 4 may be further improved through the post thermal treatment.

Furthermore, referring to FIGS. 1C and 3, the substrate 1 may be a flexible substrate. When the substrate 1 is a flexible substrate, a metal oxide thin film forming method according to an embodiment of the present invention may be applied to a roll-to-roll process. In relation to a metal oxide thin film forming method according to an embodiment of the present invention, since a thin film is formed under a relatively low deposition condition, the method may be applied to a flexible substrate. Furthermore, since a metal oxide thin patterned by single process is formed, the method may be suitable for the roll-to-roll process. First, the flowed first metal oxide precursor 2 may be injected on the substrate 1 of the first stage 110a through the micro nozzle 120 in operation S120. Then, a first metal oxide precursor layer 4′ may be formed from the first metal oxide precursor 2 injected on the substrate 1 in operation S130.

Then, the substrate 1 including the formed first metal oxide precursor layer 4′ may be transferred by the rotation of a roll 195 in a direction opposite to the first direction D1. Additionally, the transferred substrate 1 may be loaded on the second stage 110b. Then, a first metal oxide layer 4 may be formed in operation S140 by emitting electromagnetic waves on the first metal oxide precursor layer 4′. That is, the emission of the electromagnetic waves may be performed after the formation of the first metal oxide precursor layer 4′. Additionally, the emission of the electromagnetic waves may be performed on a large area of the front surface of the substrate 1. Thus, the first metal oxide precursor layer 4′ on the substrate 1 may change to the first metal oxide layer 4 collectively. The electromagnetic waves may be emitted through the first electromagnetic emitter 180a.

Furthermore, the first metal oxide precursor 4′ or the first metal oxide layer 4 may be selectively heated on the second stage 110b by using another electromagnetic wave. Thus, the conversion rate from the first metal oxide precursor layer 4′ to the first metal oxide layer 4 may be further improved. The other electromagnetic wave may be emitted through the second electromagnetic emitter 180b and may be emitted on a large area of the substrate 1. Unlike electromagnetic waves emitted from the first electromagnetic emitter 180a, the electromagnetic waves emitted from the second electromagnetic emitter 180b may be a visible or infrared light for selectively raising a temperature of the first metal oxide precursor layer 4′ and/or the first metal oxide layer 4 on the substrate 1. Especially, the second electromagnetic emitter 180b may include a flash lamp or a pulse laser and in this case, it is possible to minimize a heating effect applied to the entire substrate 1 by effectively and instantaneously controlling a temperature of the first metal oxide precursor layer 4′ and/or the first metal oxide layer 4. In addition to this, since a metal oxide thin film forming method according to an embodiment of the present invention is an atmospheric pressure process, unlike an area on the first stage 110a where the micro nozzle 120 is disposed, an area on the second state 110b where the electromagnetic emitters 180a and 180a are disposed may adjust a vapor atmosphere in stages. Thus, it is possible to further effectively induce the chemical change from the first metal oxide precursor layer 4′ to the first metal oxide layer 4. For example, when an oxidizing gas such as oxygen, dioxide, or ozone for facilitating the oxidation passes through an area on the second stage 110b, an efficient conversion to a metal oxide may be possible under a lower temperature atmosphere.

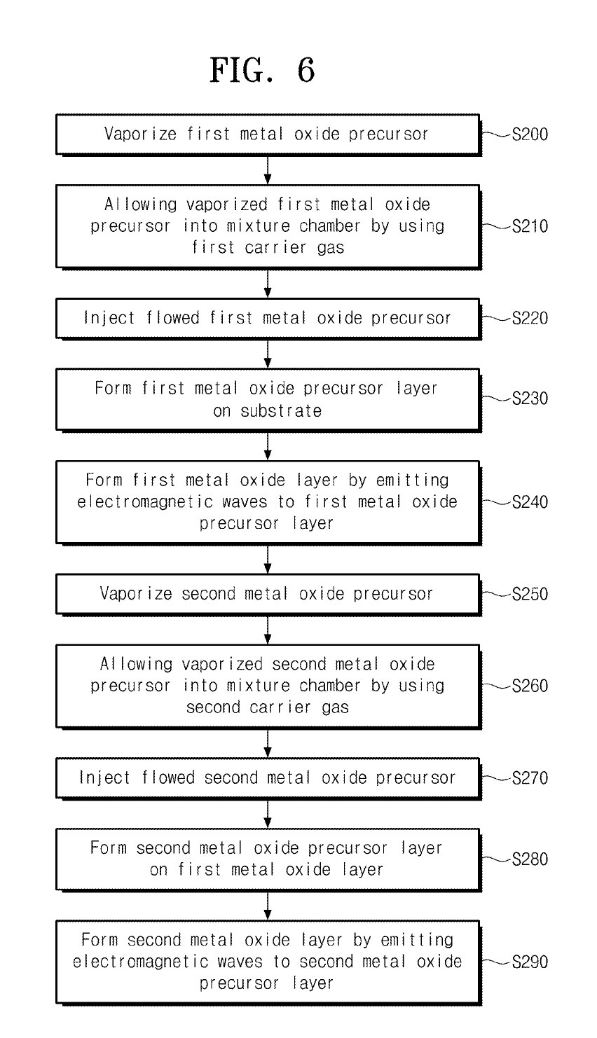

FIG. 6 is a flowchart illustrating a method of forming a metal oxide thin film according to another embodiment of the present invention.

Referring to FIGS. 2A and 6, a first metal oxide precursor 2a may be vaporized in operation S200. The vaporized first metal oxide precursor 2a may flow into the mixture chamber 230 by using a first carrier gas 3a in operation S210. The flowed first metal oxide precursor 2a may be injected on the substrate 1 through the micro nozzle 220 connected to a lower end of the mixture chamber 130 in operation S220. Then, a first metal oxide precursor layer may be formed from the first metal oxide precursor 2a injected on the substrate 1 in operation S230. A first metal oxide layer 4a may be formed in operation S240 by emitting electromagnetic waves on the first metal oxide precursor layer. Operations S200 to S240 are identical to those of the metal oxide thin film forming method described with reference to FIGS. 1A and 3.

A second metal oxide precursor 2b may be vaporized in operation S250. The vaporized second metal oxide precursor 2b may flow into the mixture chamber 230 by using a second carrier gas 3b in operation S260. The flowed second metal oxide precursor 2b may be injected on the first metal oxide layer 4a through the micro nozzle 220 connected to a lower end of the mixture chamber 230 in operation S270. A first metal oxide precursor layer may be formed from the injected second metal oxide precursor 2b, on the first metal oxide layer 4a in operation S280. A second metal oxide layer 4b may be formed in operation S290 by emitting electromagnetic waves on the second metal oxide precursor layer. Operations S250 to S290 are identical to those of the metal oxide thin film forming method described with reference to FIGS. 1A and 3.

The second metal oxide precursor 2b may be identical to the first metal oxide precursor 2a described in the above embodiment. However, the second metal oxide precursor 2b may be different from the first metal oxide precursor 2a. For example, the first metal oxide precursor 2a may be zinc acetylacetonate and the second metal oxide precursor 2b may be indium acetylacetonate. When UV rays are emitted on the indium acetylacetonate, it may change to an indium oxide (In2O3).

After the first metal oxide layer 4a is formed first on the substrate 1 through operations S200 to S240, the second metal oxide layer 4b may be formed on the first metal oxide layer 4a through operations S250 to S290. That is, the first metal oxide layer 4a formed using the first metal oxide precursor layer and the second metal oxide layer 4b formed using the second metal oxide precursor layer may form a sequentially-stacked multilayer structure. This will be described in more detail below.

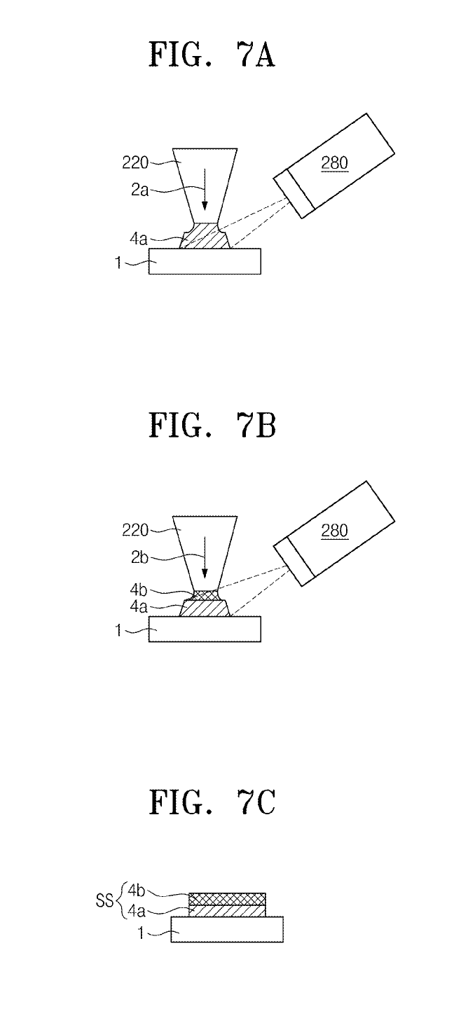

FIGS. 7A to 7C are sectional views illustrating a method of forming a multilayer structure SS where a first metal oxide layer 4a and a second metal oxide layer 4b are sequentially stacked.

Referring to FIGS. 2A and 7, the first metal oxide layer 4a may be formed on a substrate 1. The forming of the first metal oxide layer 4a may further include performing operations S200 to S240. As the first metal oxide layer 4a is formed, only the first metal oxide precursor 2a may be injected from the micro nozzle 220. In more detail, as the second metal oxide precursor 2b is prevented from flowing into the mixture chamber 230 by closing the second carrier gas valve 260b, only the first metal oxide precursor 2a may be injected through the micro nozzle 220.

For another example, although not shown in the drawing, after the first metal oxide precursor 2a is injected on the substrate 1, a first metal oxide precursor layer may be formed without additional electromagnetic processing. Then, a second metal oxide layer 4b may be formed ion the first metal oxide precursor layer.

Referring to FIGS. 2A and 7B, the second metal oxide layer 4b may be formed on the first metal oxide layer 4a. The forming of the second metal oxide layer 4b may further include performing operations S250 to S290. As the second metal oxide layer 4b is formed, only the second metal oxide precursor 2b may be injected from the micro nozzle 220. In more detail, as the first metal oxide precursor 2a is prevented from flowing into the mixture chamber 230 by closing the first carrier gas valve 260a, only the second metal oxide precursor 2b may be injected through the micro nozzle 220.

Referring to FIGS. 2A and 7C, the multilayer structure SS where the first metal oxide layer 4a and the second metal oxide layer 4b are sequentially stacked may be formed. For another example, although not shown in the drawing, other layers may be disposed between the first metal oxide layer 4a and the second metal oxide layer 4b. In this case, the first metal oxide layer 4a is formed first and the other layers are formed. Then, the second metal oxide layer 4b may be formed spaced apart from the first metal oxide layer 4a

Furthermore, referring to FIGS. 2B and 6, the substrate 2 may be a flexible substrate. When the substrate 1 is a flexible substrate, a metal oxide thin film forming method according to an embodiment of the present invention may be applied to a roll-to-roll process. This may be identical to the metal oxide thin film forming method described with reference to FIGS. 1C and 3.

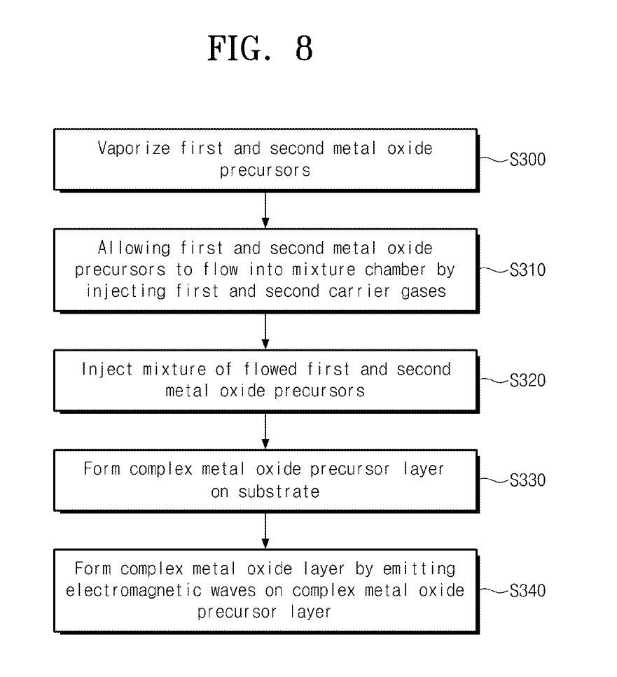

FIG. 8 is a flowchart illustrating a method of forming a metal oxide thin film according to another embodiment of the present invention.

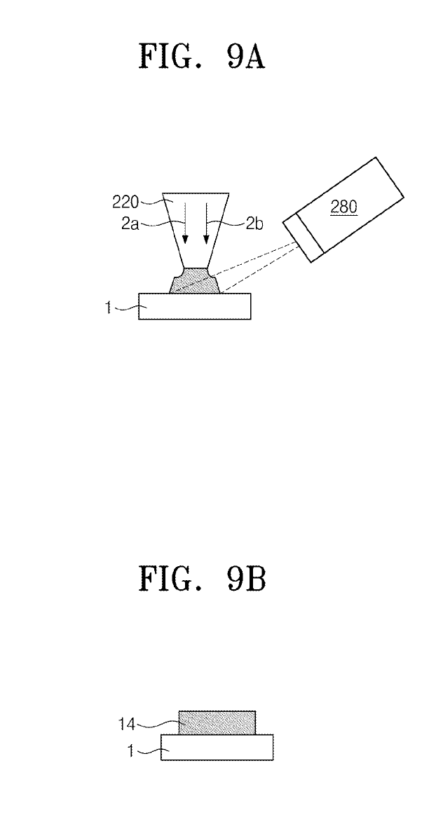

FIGS. 9A and 9B are sectional views illustrating a method of forming a complex metal oxide layer 14 on a substrate 1.

Referring to FIGS. 2A and 8, a first metal oxide precursor 2a and a second metal oxide precursor 2b may be vaporized separately in operation S300. The first metal oxide precursor 2a and the second metal oxide precursor 2b are described in the above embodiment of the present invention. For example, the first metal oxide precursor 2a may be zinc acetylacetonate and the second metal oxide precursor 2b may be indium acetylacetonate.

The first metal oxide precursor 2a and the second metal oxide precursor 2b may be received in a first storage chamber 240a and a second storage chamber 240b, respectively. The first metal oxide precursor 2a may be heated through a first heater 245a in the first storage chamber 240a and the second metal oxide precursor 2b may be heated through a second heater 245b in the second storage chamber 240b.

The vaporizing of the first metal oxide precursor 2a and the second metal oxide precursor 2b may include vaporizing the first metal oxide precursor 2a and the second metal oxide precursor 2b separately without a solvent.

Referring to FIGS. 2A and 8, the vaporized first metal oxide precursor 2a and the vaporized second metal oxide precursor 2b may flow into the mixture chamber 230 by using a first carrier gas 3a and a second carrier gas 3b respectively in operation S310. The vaporized first metal oxide precursor 2a may transfer to the mixture chamber 230 through a first transfer passage 250a between the first storage chamber 240a and the mixture chamber 230. The vaporized second metal oxide precursor 2b may transfer to the mixture chamber 230 through a second transfer passage 250b between the second storage chamber 240a and the mixture chamber 230. At this point, the first carrier gas 3a may transfer the first metal oxide precursor 2a as sequentially flowing along the first storage chamber 240a and the mixture chamber 230. The second carrier gas 3b may transfer the second metal oxide precursor 2b as sequentially flowing along the second storage chamber 240b and the mixture chamber 230.

The amount of the first metal oxide precursor 2a flowing into the mixture chamber 230 and the amount of the second metal oxide precursor 2b flowing into the mixture chamber 230 may be adjusted through the following method.

For example, by controlling opening/closing cycles per unit time, the number of openings/closings, or an opening/closing time ratio of each of a first carrier gas valve 260a and a second carrier gas valve 260b, the flow rata and transfer of each of the first carrier gas 3a and the second carrier gas 3b may be controlled. Thus, the amount of the first metal oxide precursor 2a flowing into the mixture chamber 230 and the amount of the second metal oxide precursor 2b flowing into the mixture chamber 230 may be adjusted selectively. The first carrier gas valve 260a and the second carrier gas valve 260b may be controlled separately by using the controller 290.

For another example, by adjusting the flow rate of each of the first carrier gas 3a flowing into the first storage chamber 240a and the second carrier gas 3b flowing into the second storage chamber 240b, the amount of the first metal oxide precursor 2a flowing into the mixture chamber 230 and the amount of the second metal oxide precursor 2b flowing into the mixture chamber 230 may be adjusted selectively. The flow rates of the first carrier gas 3a and the second carrier gas 3b may be adjusted by using a first carrier gas supplier 270a and a second carrier gas supplier 270b. Or, the flow rates may be adjusted by controlling the first carrier gas valve 260a and the second carrier gas valve 260b.

For another example, by adjusting an internal temperature of each of the first storage chamber 240a and the second storage chamber 240b, each of the amount of the sublimated first metal oxide precursor 2a and the amount of the sublimated second metal oxide precursor 2b may be adjusted. Or, by adjusting a pressure of each of the first storage chamber 240a and the second storage chamber 240b, each of the amount of the sublimated first metal oxide precursor 2a and the amount of the sublimated second metal oxide precursor 2b may be adjusted. For example, the first storage chamber 240a may include a first heater 245a and the second storage chamber 240b may include a second heater 245b. The controller 290 may control the first heater 245a and the second heater 245b separately, thereby adjusting the amounts of the sublimated first and second metal oxide precursors 2a and 2b. As the amounts of the sublimated first and second metal oxide precursors 2a and 2b are increased, the amounts of the first and second metal oxide precursors 2a and 2b flowing into the mixture chamber 230 may be increased.

Through the above-mentioned methods, a ratio of the first metal oxide precursor 2a and the second metal oxide precursor 2b flowing into the mixture chamber 230 may be adjusted.

The first metal oxide precursor 2a and the second metal oxide precursor 2b flowing into the mixture chamber 230 may be uniformly mixed with each other as transferring to the mixture chamber 230. As a result, a mixture of the first metal oxide precursor 2a and the second metal oxide precursor 2b may be formed in the mixture chamber 230. The composition of the mixture may be determined by a ratio of the first metal oxide precursor 2a and the second metal oxide precursor 2b. Furthermore, a third carrier gas 3c flowing into the mixture chamber 230 may help transferring the first metal oxide precursor 2a and the second metal oxide precursor 2b in the mixture chamber 230.

Referring to FIGS. 2A, 8 and 9A, the mixture of the flowed first metal oxide precursor 2a and second metal oxide precursor 2b may be injected on the substrate 1 through the micro nozzle 220 connected to a lower end of the mixture chamber 230 in operation S320. Then, a complex metal oxide precursor layer may be formed from the mixture injected on the substrate 1 in operation S330.

The mixture of the first metal oxide precursor 2a and the second metal oxide precursor 2b may transfer to the micro nozzle 220 by the third carrier gas 3c along the mixture chamber 230. Then, the mixture may be jet-injected on the substrate 1 through the micro nozzle 220 by the third carrier gas 3c. The injection speed and amount of the injected mixture may be adjusted by using the third carrier gas 3c. The micro nozzle 220 may include a third heater (not shown) and may prevent the mixture from being condensed by using the third heater.

As the mixture injected from the micro nozzle 220 is cooled and condensed, the complex metal oxide precursor layer may be formed. For example, the complex metal oxide precursor layer may be a zinc-indium acetylacetonate layer. The zinc-indium acetylacetonate layer is not in a state in which zinc acetylacetonate and indium acetylacetonate are mixed but may exist in one compound state in which they are chemically compound. This is because they can cause chemical reaction with each other as the mixture is condensed due to a change from a high temperature into a low temperature or through a post processing process.

Referring to FIGS. 2A, 8, 9A, and 9B, a complex metal oxide layer 14 may be formed in operation S340 by emitting by emitting electromagnetic waves on the complex metal oxide precursor layer. When electromagnetic waves are emitted on the complex metal oxide precursor layer, as C and H therein leave, the complex metal oxide layer 14 may be formed. For example, when the complex metal oxide precursor layer is a zinc-indium acetylacetonate layer, an indium zinc oxide (InZnₓO_{y}) layer may be formed by emitting UV rays on the zinc-indium acetylacetonate layer. The electromagnetic waves may include at least one of UV, IR, visible ray, microwave, gamma-ray, and X-ray and may be appropriately selected by those skilled in the art according to the types of the first metal oxide precursor 2a and the second metal oxide precursor 2b.

In the complex metal oxide layer 14, a composition ratio of a first metal and a second metal configuring it may be determined by the composition of the injected mixture. Furthermore, as described above, the composition of the mixture may be determined according to the amount of the first metal oxide precursor 2a flowing into the mixture chamber 230 and the amount of the second metal oxide precursor 2b flowing into the mixture chamber 230. Accordingly, a metal oxide thin film forming method according to an embodiment of the present invention may easily adjust the composition of the complex metal oxide layer 14 by controlling the flow rate of a carrier gas or the sublimation condition of the first and second metal oxide precursors 2a and 2b.

When the composition ratio of the complex metal oxide layer 14 is changed, its electrical characteristics may change. For example, when an oxide layer having a large resistance needs to be formed on a semiconductor device, a complex metal oxide layer 14 having a large resistance may be formed by changing the composition ratio. On the contrary, when an oxide layer having a small resistance needs to be formed on a semiconductor device, a complex metal oxide layer 14 having a small resistance may be formed by changing the composition ratio. Furthermore, the complex metal oxide layer 14 having different electrical characteristics may be formed through single process.

Furthermore, referring to FIGS. 2B and 8, the substrate 2 may be a flexible substrate. When the substrate 1 is a flexible substrate, a metal oxide thin film forming method according to an embodiment of the present invention may be applied to a roll-to-roll process. This may be identical to the metal oxide thin film forming method described with reference to FIGS. 1C and 3.

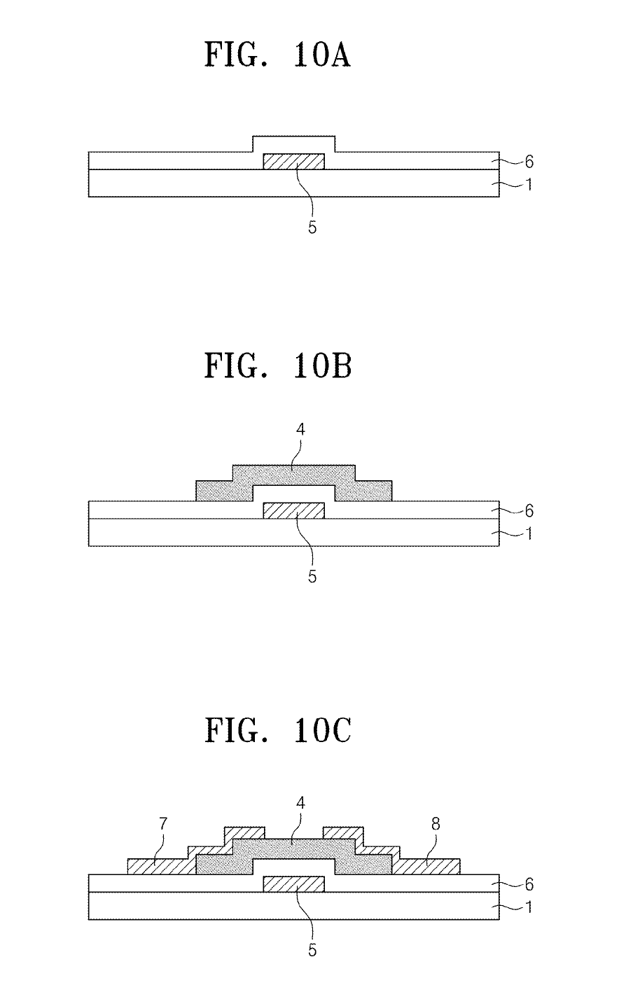

FIGS. 10A to 10C are cross-sectional views illustrating a method of fabricating a thin film transistor according to an embodiment of the present invention. For example, the thin film transistor may be fabricated using a thin film printing device shown in FIG. 1A according to an embodiment of the present invention.

Referring to FIG. 10A, a gate electrode 5 may be formed on a substrate 1. The gate electrode 5 may be formed by depositing a first conductive layer on the substrate 1 and then selectively patterning it. The first conductive layer may include a low resistance opaque conductive material such as Al, an Al alloy, W, Cu, Ni, Cr, Mo, Ti, Pt, and Ta. The first conductive layer may include an opaque conductive material such as ITO and IZO. The first conductive layer may be a multilayer structure where the low resistance opaque conductive material and the opaque conductive material are sequentially stacked.

A gate insulating layer 6 may be formed on the gate electrode 5. In more detail, a gate insulating layer 6 including an inorganic insulating layer such as SiNₓ and SiO₂ or a high-k oxide layer such as an Hf oxide layer, and an Al oxide layer may be formed on the substrate 1 where the gate electrode 5 is formed. The gate insulating layer 6 may be formed to completely cover the gate electrode 5 and accordingly, the gate electrode 5 may be disposed between the gate insulating layer 6 and the substrate 1. Although not particularly limited, the gate insulating layer 6 may be formed through a chemical vapor deposition (CVD) process or a plasma-enhanced chemical vapor deposition (PECVD) process.

Referring to FIG. 10A, a metal oxide thin film 4 may be formed on the gate insulating layer 6. The metal oxide thin film 4, as an active layer, may be an amorphous zinc oxide semiconductor layer.

The metal oxide thin film 4 may be formed according to the metal oxide thin film forming method described with reference to FIGS. 1A and 3. Referring to FIGS. 1A, 3, and 10B, the metal oxide thin film forming method includes vaporizing a first metal oxide precursor 2 in operation S100, allowing the vaporized first metal oxide precursor 2 to flow into the mixture chamber 130 by using a first carrier gas 3 in operation S110, injecting the flowed first metal oxide precursor 2 on the gate insulating layer 6 through the micro nozzle 120 connected to a lower end of the mixture chamber 130 in operation S120, forming a first metal oxide precursor layer from the first metal oxide precursor 2 injected on the gate insulating layer 6 in operation S130, and forming a first metal oxide layer 4 by emitting electromagnetic waves on the first metal oxide precursor layer in operation S140. Herein, the first metal oxide precursor 2 may be zinc acetylacetonate and the first metal oxide layer 4, as the metal oxide thin film 4, may be a ZnO layer. Operations S100 to S140 are described above.

For another example, the metal oxide thin film 4 may be formed according to the metal oxide thin film forming method described with reference to FIGS. 2A and 8. That is, the metal oxide thin film 4 may be a complex metal oxide layer. Herein the first metal oxide precursor 2a may be zinc acetylacetonate and the second metal oxide precursor 2b may be indium acetylacetonate. The complex metal oxide layer may be an amorphous zinc oxide-based compound semiconductor layer and in more detail may be an InZnₓO_{y} layer.

The metal oxide thin film 4 may have a pattern formed only on a partial area of the gate insulating layer 6. In more detail, from the plane viewpoint, the metal oxide thin film 4 may have a pattern overlapping the gate electrode 5. According to an embodiment of the present invention, through the method of forming the predetermined pattern 4′P described with reference to FIGS. 4A to 4C, a pattern of the metal oxide thin film 4 may be formed. Accordingly, without an additional patterning process for the metal oxide thin film 4, the pattern may be formed.

Referring to FIG. 10C, a source electrode 7 and a drain electrode 8 may be formed on the metal oxide thin film 4. The source electrode 7 and the drain electrode 8 may be formed by depositing a second conductive layer on the metal oxide thin film 4 and the exposed gate insulating layer 6 and then selectively patterning it. The second conductive layer may be formed completely cover the top surface of the metal oxide thin film 4 and the top surface of the exposed gate insulating layer 6. At this point, the source electrode 7 and the drain electrode 8 may be simultaneously formed from the second conductive layer.

The second conductive layer may include a low resistance opaque conductive material such as Al, an Al alloy, W, Cu, Ni, Cr, Mo, Ti, Pt, and Ta. The second conductive layer may include an opaque conductive material such as ITO and IZO. The second conductive layer may be a multilayer structure where the low resistance opaque conductive material and the opaque conductive material are sequentially stacked.

The source electrode 7 and the drain electrode 8 may be disposed on the same layer but may be spaced apart from each other. Furthermore, the source electrode 7 and the drain electrode 8 may electrically contact the metal oxide thin film 4.

Though the method of fabricating a thin film transistor described with reference to FIGS. 10A to 10C, a thin film transistor may be provided. Although not additionally shown in the drawing, a contact electrically connected to the source electrode 7 and the drain electrode 8 may be formed and a protective layer protecting the thin film transistor may be formed.

### Experimental Example 1

According to a metal oxide thin film forming method according to an embodiment of the present invention, a metal oxide thin film was fabricated and its characteristics were examined as follows.

Zinc acetylacetonate, i.e., an organic metal compound, was introduced as a metal oxide precursor to a storage chamber in a metal oxide thin film printing device. The zinc acetylacetonate was vaporized by heating the storage chamber and then injected on a substrate. At this point, helium was used as carrier gas. After the injection, a zinc acetylacetonate layer was formed on the substrate (comparative example 1).

A thermal treatment process was performed while UV rays were emitted on the zinc acetylacetonate layer. The UV rays had a wavelength of about 250 nm and were emitted in the atmosphere. At this point, the substrate was maintained at a temperature of about 200° C. Thus, a zinc oxide layer was formed from the zinc acetylacetonate layer (example 1).

The following experiments were performed on comparative example 1 in which zinc acetylacetonate was injected and deposited and example 1 in which UV and thermal treatments were performed on comparative example 1 additionally,

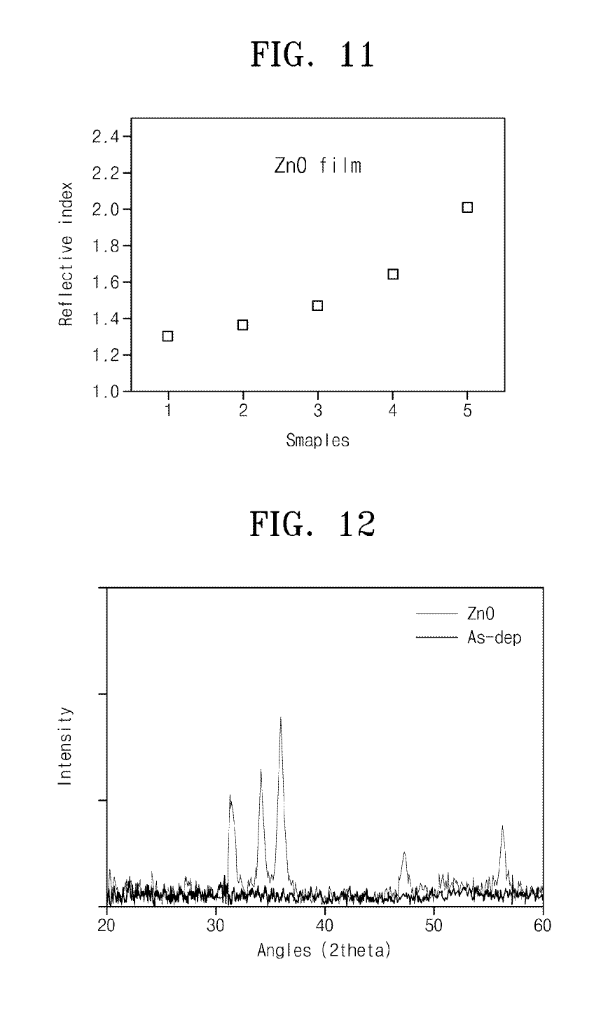

First, a refractive index of each of a thin film of comparative example 1 and a thin film of example 1 was measured and shown in FIG. 11. Sample 1 of FIG. 11 represents comparative example 1 and Sample 5 represents example 1. Besides that, Samples 2 to 4 of FIG. 11 were samples in which the degrees of performing UV and thermal treatments on comparative example 1 were sequentially different from each other.

As shown in FIG. 11, comparative example 1 (sample 1) has a refractive index of about 1.30 and thus it is confirmed that carbon is contained. However, since example 1 (Sample 5) has a refractive index of about 2.01, it is confirmed that the refractive index is almost identical to that of a zinc oxide.

After X-ray diffraction analysis was performed on each of the thin film of comparative example 1 and the thin film of example 1, its result is shown in FIG. 12.

As shown in FIG. 12, a thin film of comparative example 1 (As-dep) does not show specific crystalline but a thin film of example 1 (ZnO) shows a diffraction pattern of a zinc oxide.

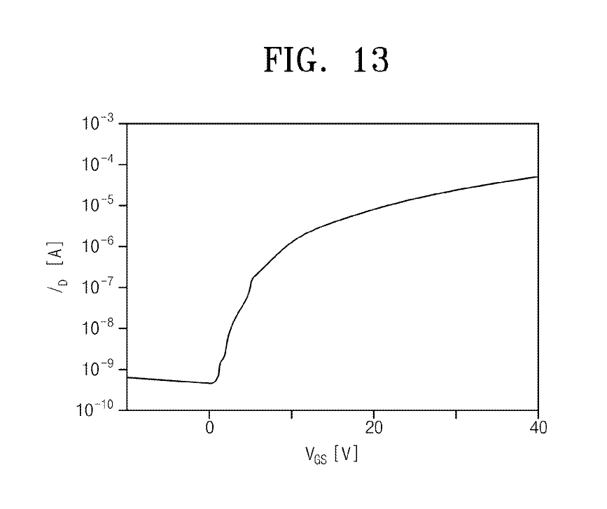

By analyzing electrical characteristics of the thin film of example 1, it result is shown in FIG. 13.

As shown in FIG. 13, in relation to the thin film of example 1, the IV curve represents n-type semiconductor characteristics.

Through the above experiments, a metal oxide thin film forming method according to an embodiment of the present invention may confirm that a metal oxide precursor changes to a metal oxide efficiently through the emission of electromagnetic waves. Additionally, it is confirmed that the metal oxide thin film may have semiconductor characteristics and thus may serve as an active layer of a thin film transistor.

According to an embodiment of the present invention, by performing a vapor jet printing process using a metal oxide precursor such as an organic metal compound, compared to a case using a metal oxide directly, a metal oxide thin film may be formed under a relatively low deposition condition. Accordingly, a substrate and other thin films sensitive to process conditions may b used without any particular limitations. Moreover, according to an embodiment of the present invention, without an additional patterning process, a pattern may be formed instantaneously by printing a metal oxide thin film. Furthermore, a roll-to-roll process applied to a flexible substrate may be realized using the low deposition conditions and productivity may be improved by performing a large area electromagnetic emission thereon.

Furthermore, according to an embodiment of the present invention, by using at least two different metal oxide precursors, a complex metal oxide layer including a metal oxide thin film having a multilayer structure or at least two metal components may be formed through single process. Additionally, in the case of the complex metal oxide thin film, its composition may be adjusted easily.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A metal oxide thin film forming method comprising:
vaporizing a first metal oxide precursor at a source chamber;
allowing the vaporized first metal oxide precursor to flow into a mixture chamber by using a first carrier gas;
injecting the flowed first metal oxide precursor on a substrate through a micro nozzle connected to the mixture chamber to form a first metal oxide precursor layer on the substrate; and
emitting electromagnetic waves to the first metal oxide precursor layer to form a first metal oxide layer.

2. The method of claim 1, wherein the first metal oxide precursor is an organic metal compound that can be vaporized at a higher vacuum pressure or atmosphere and a lower temperature than a first metal oxide including the same metal element as the first metal oxide precursor.

3. The method of claim 1, wherein the vaporizing of the first metal oxide precursor comprises vaporizing the first metal oxide precursor under a condition that a solvent does not exist.

4. The method of claim 1, wherein the forming of the first metal oxide precursor layer comprises:
injecting the flowed first metal oxide precursor to a first area on the substrate to form the first metal oxide precursor layer on the first area; and
injecting the flowed first metal oxide precursor to a second area adjacent to the first area to form a predetermined pattern,
wherein the predetermined pattern comprises a first metal oxide precursor layer on the first area and a first metal oxide precursor layer on the second area connected thereto.

5. The method of claim 1, wherein an amount of the first metal oxide precursor flowing into the mixture chamber is adjusted by a flow rate of the first carrier gas or the temperature of the source chamber, mixing chamber or substrate.

6. The method of claim 1, further comprising:
vaporizing a second metal oxide precursor;
allowing the vaporized second metal oxide precursor to flow into the mixture chamber by using a second carrier gas;
injecting the flowed second metal oxide precursor on the substrate through the micro nozzle connected to the mixture chamber to form a second metal oxide precursor layer on the first metal oxide precursor layer or the first metal oxide layer; and
forming a second metal oxide layer by emitting electromagnetic waves to the second metal oxide precursor layer.

7. The method of claim 6, wherein the first metal oxide layer formed using the first metal oxide precursor layer and the second metal oxide layer formed using the second metal oxide precursor layer are stacked sequentially.

8. The method of claim 1, wherein the emitting of the electromagnetic waves is performed while the first metal oxide precursor layer is formed or after the first metal oxide precursor layer is formed.

9. The method of claim 1, wherein the forming of the first metal oxide layer comprises changing a portion of the first metal oxide precursor layer into the first metal oxide layer by emitting electromagnetic waves to a predetermined area of the first metal oxide precursor layer.

10. The method of claim 1, wherein the electromagnetic waves comprise at least one of ultraviolet ray, infrared ray, visible ray, microwave, gamma-ray, and X-ray.

11. The method of claim 1, wherein the forming of the first metal oxide layer further comprises performing a post thermal treatment before, during or after electromagnetic emission.

12. A metal oxide thin film forming method comprising:
vaporizing a first metal oxide precursor and a second metal oxide precursor separately;
allowing the vaporized first metal oxide precursor and second metal oxide precursor to flow into a mixture chamber by using a first carrier gas and a second carrier gas, respectively, to form a mixture of the first metal oxide precursor and the second metal oxide precursor;
injecting the mixture on a substrate through a micro nozzle connected to the mixture chamber to form a complex metal oxide precursor layer on the substrate; and
forming a complex metal oxide layer by emitting electromagnetic waves to the complex metal oxide precursor layer.

13. The method of claim 12, wherein
an amount of the first metal oxide precursor flowing into the mixture chamber and an amount of the second metal oxide precursor flowing into the mixture chamber are adjusted by a flow rate of the first carrier gas and a flow rate of the second carrier gas, respectively; and
a composition of the complex metal oxide layer is adjusted by the amount of the first metal oxide precursor flowing into the mixture chamber and the amount of the second metal oxide precursor flowing into the mixture chamber.

14. A metal oxide thin film printing device comprising:
a first storage chamber receiving a first metal oxide precursor and including a first heater for vaporizing the first metal oxide precursor;
a mixture chamber connected to the first storage chamber and into which the vaporized first metal oxide precursor flows together with a first carrier gas, the first metal oxide precursor and the first carrier gas being transferred to a micro nozzle connected to the mixture chamber;
a first carrier gas valve adjusting an amount of the first metal oxide precursor flowing into the mixture chamber;
the micro nozzle injecting the first metal oxide precursor;
a first electromagnetic emitter emitting electromagnetic waves to change the first metal oxide precursor into a first metal oxide;
a first stage where a substrate is loaded and a first metal oxide precursor layer is formed on the substrate; and
a second stage where the substrate transferred from the first state is loaded and a first metal oxide layer is formed from the first metal oxide precursor layer by emitting the electromagnetic waves on the substrate.

15. The device of claim 14, wherein the substrate is a flexible substrate and the flexible substrate is transferred from the first state to the second stage by a roll.

16. The device of claim 14, further comprising a deposition chamber including the first storage chamber, the mixture chamber, the micro nozzle, the first electromagnetic emitter, the first state, and the second stage in the device.

17. The device of claim 14, further comprising a second electromagnetic emitter emitting electromagnetic waves to selectively heat the first metal oxide precursor layer or the first metal oxide layer, on the second stage.

18. The device of claim 14, further comprising:
a second storage chamber receiving a second metal oxide precursor and including a second heater for vaporizing the second metal oxide precursor; and
a second carrier gas valve adjusting an amount of the second metal oxide precursor flowing into the mixture chamber.
wherein the mixture chamber is connected to the second storage chamber and the vaporized second metal oxide precursor flows into the mixture chamber together with a second carrier gas; and
the micro nozzle injects a first metal oxide precursor, a second metal oxide precursor, or a mixture thereof.

19. The device of claim 18, wherein the mixture chamber mixes the first metal oxide precursor and the second metal oxide precursor and the micro nozzle injects a mixture of the first metal oxide precursor and the second metal oxide precursor.

20. The device of claim 18, further comprising a controller separately controlling the first carrier gas valve and the second carrier gas valve.
